(19) United States
(12) Patent Application Publication
(10) Pub. No.: US 2026/0076241 A1
(43) Pub. Date: Mar. 12, 2026

(54) METHOD FOR MANUFACTURING SINTER BONDING FILM, AND METHOD FOR MANUFACTURING POWER SEMICONDUCTOR PACKAGE

(71) Applicant: FOUNDATION FOR RESEARCH AND BUSINESS, SEOUL NATIONAL UNIVERSITY OF SCIENCE AND TECHNOLOGY, Seoul (KR)

(72) Inventors: Jonghyun LEE, Seoul (KR); Woo Lim CHOI, Seoul (KR)

(73) Assignee: FOUNDATION FOR RESEARCH AND BUSINESS, SEOUL NATIONAL UNIVERSITY OF SCIENCE AND TECHNOLOGY, Seoul (KR)

(21) Appl. No.: 19/106,644

(22) PCT Filed: Mar. 23, 2023
(86) PCT No.: PCT/KR2023/003841

§ 371 Date: Feb. 26, 2025

(30) Foreign Application Priority Data
Sep. 1, 2022 (KR) 10-2022-0110513

(51) Int. Cl. H01L 23/00

(52) U.S. Cl. CPC H10W 72/013; H10W 72/073; H10W 72/30; H10W 72/01333; H10W 72/01361; H10W 72/01365; H10W 72/07331; H10W 72/07332; H10W 72/325; H10W 72/352; H10W 72/354; H10W 72/951

(57) ABSTRACT

A method for manufacturing sinter bonding film, includes: preparing a resin formulation; preparing a metal filler mixture; mixing the resin formulation and the metal filler mixture, thereby preparing a paste for film manufacturing; and manufacturing a sinter bonding film by using the paste for film manufacturing. The metal filler mixture includes a metal powder and a reducing agent, copper metal (Cu) corresponds to respective particles in the metal powder, and the surface of the respective particles in the metal powder undergoes acid treatment or non-treatment.

### CROSS-REFERENCE TO PRIOR APPLICATIONS

This Application is a National Stage Patent Application of PCT International Application No. PCT/KR2023/003841 (filed on Mar. 23, 2023), which claims priority to Korean Patent Application No. 10-2022-0110513 (filed on Sep. 1, 2022), which are all hereby incorporated by reference in their entirety.

### BACKGROUND

The present invention relates to a method of forming a sinter-bonding film and a method of manufacturing a power semiconductor package to provide a bonding part used at an operation temperature of a power semiconductor in a power semiconductor package.

In general, power semiconductors are semiconductors that perform power conversion, transformation, processing, distribution, and control, and are the core of power modules for electrical driving of various electrical and electronic devices that require power transmission and control.

Power semiconductors are classified into metal oxide semiconductor field effect transistors (MOSFETs), insulated gate bipolar transistors (IGBTs), diodes, thyristors and the like.

In addition, the power semiconductors are mounted on power modules in electrical and electronic devices such as electric vehicles (EVs), hybrid electric vehicles (HEVs), high-speed trains, renewable energy generation, energy storage devices, and mobile devices. Here, the power modules require high energy conversion efficiency and high reliability and are configured as power semiconductor packages.

Meanwhile, as shown in FIG. 1, the power semiconductor package 50 generally includes a first copper layer 13, a metal oxide substrate layer 16, a second copper layer 19, a solder layer 30, and a power semiconductor chip 40 that are sequentially laminated. Here, the first copper layer 13, the metal oxide substrate layer 16, and the second copper layer 19 constitute a direct bonded copper (DBC) substrate 20.

In the power semiconductor package 50, the solder layer 30 is made of a Sn (tin)-based alloy or a Pb (lead)-based alloy having a melting point of 217° C. to 308° C. The solder layer 30 has been widely used as a bonding part of a silicon-based power semiconductor chip 40 that has a maximum operation temperature of about 150° C.

However, as the global energy crisis and environmental pollution issues become more serious, interest in sustainable, eco-friendly technologies is increasing, and electric vehicles are produced all over the world. Accordingly, the issue of increasing the energy conversion efficiency of electric vehicle power modules has become an issue, and a change to a high-operation temperature greater than 150° C. is required along with the replacement of power semiconductor chips 40.

Specifically, in hybrid electric vehicles or pure electric vehicles, conventional silicon-based power semiconductor chips 40 are being replaced with power semiconductor chips based on wide band gap (WBG) compound semiconductors (SiC, GaN, artificial diamond, etc.) with excellent energy conversion efficiency (not shown in the drawing). However, the operating temperature of the power semiconductor chips based on the compound semiconductors may rise to 200°C. to 300° C. Therefore, the solder layer 30 cannot be applied to a power semiconductor package equipped with the power semiconductor chips based on the compound semiconductors.

This is because, although the solder layer 30 used as a bonding part of a compound semiconductor-based power semiconductor chip is made of a solder alloy that melts at the operating temperature of the compound semiconductor-based power semiconductor or has a melting point that is slightly higher than the operating temperature of the compound semiconductor-based power semiconductor, the mechanical properties of the solder alloy are greatly deteriorated in a high-temperature operating environment. Therefore, the solder alloy does not exhibit mechanical properties of a bonding part and may be easily broken.

Therefore, when the solder layer 30 is used as an alternative to this in a compound semiconductor-based power semiconductor chip, it is replaced with a bonding part layer sintered with silver (Ag) particles. The sinter-bonding layer exhibits the characteristics of a silver bulk metal by sintering a silver powder and thus maintains excellent bonding strength and long-term bonding reliability even in a high-temperature operating environment of a compound semiconductor-based power semiconductor chip due to the high melting point characteristics of silver.

However, the sinter-bonding layer is made of an expensive silver material which greatly increases the manufacturing cost of the power semiconductor package, thus reducing the price competitiveness of the power semiconductor package. Korean Patent Publication No. 10-2014-0122389 discloses a conventional layer similar to the sinter-bonding layer.

### SUMMARY

Therefore, the present invention has been made in view of the above problems, and
it is an object of the present invention to provide a method for forming a sinter-bonding film and a method for manufacturing a power semiconductor package
to provide a sinter-bonding film that replaces a sinter-bonding layer made of silver (Ag) particles under a power semiconductor chip at a low cost, directly contacts the power semiconductor chip, withstands the operating temperature of the power semiconductor chip for a long time, and effectively transfers and releases heat generated by the power semiconductor chip
in order to accommodate the power semiconductor chip of a wide band gap compound in the power semiconductor package.

In accordance with an aspect of the present invention, the above and other objects can be accomplished by the provision of a method of forming a sinter-bonding film including preparing a resin formulation, preparing a metal filler mixture, mixing the resin formulation with the metal filler mixture to prepare a film-forming paste, and forming a sinter-bonding film using the film-forming paste, wherein the metal filler mixture contains a metal powder and a reducing agent, wherein a copper (Cu) metal corresponds to respective particles of the metal powder and a surface of each particle in the metal powder is subjected to acid treatment or non-treatment.

The preparing a resin formulation may include filling a first container with a resin, pouring a resin solvent into the resin in the first container, and dissolving the resin using the resin solvent to prepare a resin formulation, wherein the resin and the resin solvent are mixed in a weight ratio of 1:2 to 1:5 in the first container.

The resin may be an acrylate polymer including at least one of polymethyl acrylate (PMA), polyethyl acrylate (PEA), poly(n-butyl acrylate) (PnBA), poly(2-ethylhexyl acrylate) (PEHA), or poly(2-hydroxyethyl acrylate) (PHEA), or a methacrylate polymer including at least one of polymethyl methacrylate (PMMA), poly(N-butyl methacrylate) (PnBMA), poly(iso-butyl methacrylate) (PIBMA), poly(2-hydroxyethyl methacrylate) (PEHMA), polyhydroxyethylmethacrylate (PHEMA), or poly(N,N-dimethylamino) ethyl methacrylate (PDMAEMA).

The resin solvent may be a ketone solvent including at least one of acetone or methyl ethyl ketone (MEK), a dipolar aprotic solvent including at least one of N-methyl pyrrolidone (NMP), dimethyl acetamide (DMAC), dimethyl formamide (DMF), or dimethyl sulfoxide (DMSO), an aromatic hydrocarbon including at least one of benzene or toluene, or chloroform, isopropanol, or tetrahydrofuran (THF).

The preparing a metal filler mixture may include filling the second container with the metal powder, and pouring the reducing agent into the metal powder in the second container, wherein the metal powder includes first metal particles having a first particle size, or includes first metal particles having a first particle size and second metal particles having a second particle size larger than the first particle size, and the metal powder is prepared by mixing the first metal particles with the second metal particles in a volume ratio of 100:0 to 26:74.

Each of the first metal particles may have a particle size of 100 nm to 900 nm and each of the second metal particles may have a particle size of 1.5 μm to 25 μm.

The reducing agent may include at least one of ethylene glycol, diethylene glycol, triethylene glycol (TEG), tetraethylene glycol (TTEG), polyethylene glycol (PEG), propylene glycol, dipropylene glycol, tripropylene glycol, polypropylene glycol, glycerol, 1,4-butanediol, 1,5-pentanediol, α-terpineol, diethyl toluene diamine, diethanol amine, or triethanol amine.

The preparing a film-forming paste may include pouring the resin formulation of the first container into the metal filler mixture of the second container; and mixing the metal filler mixture with the resin formulation in the second container, wherein the film-forming paste contains 6 to 10 parts by weight of the resin, 18 to 30 parts by weight of the resin solvent, and 0.5 to 2 parts by weight of the reducing agent, with respect to 100 parts by weight of the metal filler mixture.

The forming a sinter-bonding film may include pouring the film-forming paste of the second container onto a preliminary carrier film, and spreading the film-forming paste thinly on the preliminary carrier film through a blade while moving the preliminary carrier film using a doctor blade device, or spreading the film-forming paste thinly on the preliminary carrier film through a squeegee while fixing the preliminary carrier film using a screen printing device, drying the film-forming paste on the preliminary carrier film at a temperature of 75° C. to 120°C. for 1 minute to 5 minutes to form a preliminary sinter-bonding film, and cutting the preliminary carrier film and the preliminary sinter-bonding film into a predetermined size, or ripping the preliminary sinter-bonding film on the preliminary carrier film into a predetermined size.

The reducing agent and the resin may be left along with the metal powder in the preliminary sinter-bonding film after drying the film-forming paste, the reducing agent may surround the surface of each particle in the metal powder and reduce the oxide layer on the surface of each particle after drying the film-forming paste, the resin may be disposed between respective particles in the metal powder after drying the film-forming paste to connect the particles, and the resin solvent may be removed from the preliminary sinter-bonding film while drying of the film-forming paste.

The preparing a metal filler mixture may include filling a second container with a metal powder, pouring a carboxyl group-containing acid into the metal powder in the second container to acid-treat the surface of each particle of the metal powder using the carboxyl group-containing acid, and pouring the reducing agent into the metal powder in the second container, wherein the metal powder includes first metal particles having a first particle size, or includes first metal particles having a first particle size and second metal particles having a second particle size larger than the first particle size, the metal powder is prepared by mixing the first metal particles with the second metal particles in a volume ratio of 100:0 to 26:74, and the carboxyl group-containing acid contains 1 to 5 parts by weight of the carboxylic acid with respect to 100 parts by weight of the alcohol in the second container.

Each first metal particle may have a particle size of 100 nm to 900 nm and each second metal particle may have a particle size of 1.5 μm to 25 μm.

The carboxylic acid may include at least one of formic acid, acetic acid, oxalic acid, malic acid, malonic acid, stearic acid, or succinic acid.

Each particle in the metal powder may have a rough shape after acid-treating the surface of each particle in the metal powder using the carboxyl group-containing acid.

The reducing agent may include at least one of ethylene glycol, diethylene glycol, triethylene glycol (TEG), tetraethylene glycol (TTEG), polyethylene glycol (PEG), propylene glycol, dipropylene glycol, tripropylene glycol, polypropylene glycol, glycerol, 1,4-butanediol, 1,5-pentanediol, α-terpineol, diethyl toluene diamine, diethanol amine, or triethanol amine.

The preparing a film-forming paste may include pouring the resin formulation of the first container into the metal filler mixture of the second container, and mixing the metal filler mixture with the resin formulation in the second container, wherein the film-forming paste contains 6 to 10 parts by weight of the resin, 18 to 30 parts by weight of the resin solvent, and 0.5 to 2 parts by weight of the reducing agent, with respect to 100 parts by weight of the metal filler mixture.

The forming a sinter-bonding film may include pouring the film-forming paste of the second container onto a preliminary carrier film, and spreading the film-forming paste thinly on the preliminary carrier film through a blade while moving the preliminary carrier film using a doctor blade device, or spreading the film-forming paste thinly on the preliminary carrier film through a squeegee while fixing the preliminary carrier film using a screen printing device, drying the film-forming paste on the preliminary carrier film at a temperature of 75°C. to 120° C. for 1 minute to 5 minutes to form a preliminary sinter-bonding film, and cutting the preliminary carrier film and the preliminary sinter-bonding film into a predetermined size, or ripping the preliminary sinter-bonding film on the preliminary carrier film into a predetermined size.

The reducing agent and the resin may be left along with the metal powder in the preliminary sinter-bonding film after drying the film-forming paste, the reducing agent may surround the surface of each particle in the metal powder along with the carboxyl group-containing acid and reduce the oxide layer on the surface of each particle after drying the film-forming paste, the resin may be disposed between respective particles in the metal powder after drying the film-forming paste to connect the particles, and the resin solvent is removed from the preliminary sinter-bonding film after drying of the film-forming paste.

In accordance with another aspect of the present invention, there is provided a method of manufacturing a power semiconductor package including preparing a first bonding subject on a heating stage, sequentially placing a sinter-bonding film and a second bonding subject on the first bonding subject, and applying a thermal compression sinter-bonding process to the first bonding subject, the sinter-bonding film and the second bonding subject, wherein the sinter-bonding film is formed using a metal filler mixture and a resin formulation before the thermal compression sinter-bonding process, the metal filler mixture contains a metal powder and a reducing agent, a copper (Cu) metal is applied to each particle in the metal powder, and a surface of each particle in the metal powder is subjected to acid treatment or non-treatment.

The metal powder may include first metal particles having a first particle size, or may include first metal particles having a first particle size and second metal particles having a second particle size larger than the first particle size, each of the first metal particles may have a particle size of 100 nm to 900 nm and each of the second metal particles has a particle size of 1.5 μm to 25 μm, and the metal powder may be prepared by mixing the first metal particles with the second metal particles in a volume ratio of 100:0 to 26:74.

The metal powder may include first metal particles having a first particle size, or may include first metal particles having a first particle size and second metal particles having a second particle size larger than the first particle size, each of the first metal particles may have a particle size of 100 nm to 900 nm and each of the second metal particles may have a particle size of 1.5 μm to 25 μm, the metal powder may be prepared by mixing the first metal particles with the second metal particles in a volume ratio of 100:0 to 26:74, and the surface of each first metal particle may be acid-treated using the carboxyl group-containing acid or the surface of each first metal particle and each second metal particle is acid-treated using the carboxyl group-containing acid.

The carboxyl group-containing acid may contain 1 to 5 parts by weight of carboxylic acid with respect to 100 parts by weight of alcohol, and the carboxylic acid may include at least one of formic acid, acetic acid, oxalic acid, malic acid, malonic acid, stearic acid, or succinic acid.

Each particle in the metal powder may have a rough shape after acid-treatment of the surface of each particle in the metal powder using the carboxyl group-containing acid.

The resin may be an acrylate polymer including at least one of polymethyl acrylate (PMA), polyethyl acrylate (PEA), poly(n-butyl acrylate) (PnBA), poly(2-ethylhexyl acrylate) (PEHA), or poly(2-hydroxyethyl acrylate) (PHEA), or a methacrylate polymer including at least one of polymethyl methacrylate (PMMA), poly(N-butyl methacrylate) (PnBMA), poly(iso-butyl methacrylate) (PIBMA), poly(2-hydroxyethyl methacrylate) (PEHMA), polyhydroxyethylmethacrylate (PHEMA), or poly(N,N-dimethylamino) ethyl methacrylate (PDMAEMA), and the resin may be disposed between the respective particles in the metal powder to connect the particles.

The reducing agent may include at least one of ethylene glycol, diethylene glycol, triethylene glycol (TEG), tetraethylene glycol (TTEG), polyethylene glycol (PEG), propylene glycol, dipropylene glycol, tripropylene glycol, polypropylene glycol, glycerol, 1,4-butanediol, 1,5-pentanediol, α-terpineol, diethyl toluene diamine, diethanol amine, or triethanol amine, and the reducing agent may surround the surface of each particle in the metal powder and reduce the oxide layer on the surface of each particle during the thermal compression sinter-bonding process.

The preparing the first bonding subject on the heating stage may include placing a first tray containing a plurality of first bonding subjects around the heating stage, and placing the first bonding subject from the first tray on the heating stage using a first pick-up tool, wherein the first bonding subject includes a direct bonded copper (DBC) substrate or an active brazing ceramic substrate, which includes a first copper layer, a metal oxide substrate layer, and a second copper layer that are sequentially laminated.

The sequentially placing the sinter-bonding film and the second bonding subject on the first bonding subject may include placing a second tray containing a plurality of unit laminates, each including the sinter-bonding film and the carrier film, around the heating stage, placing a third tray containing a plurality of second bonding subjects around the heating stage, placing the sinter-bonding film and the carrier film on the first bonding subject from the second tray using a second pick-up tool, separating the carrier film from the sinter-bonding film, and placing the second bonding subject on the sinter-bonding film from the third tray using a third pick-up tool.

The applying the thermal compression sinter-bonding process to the first bonding subject, the sinter-bonding film and the second bonding subject may include bonding the first and second bonding subjects to the sinter-bonding film while performing the thermal compression sinter-bonding process on the first bonding subject, the sinter-bonding film, and the second bonding subject using the heating stage and the third pick-up tool, and the thermal compression sinter-bonding process may be performed in an air atmosphere or a nitrogen atmosphere at a temperature of 300° C. to 370°C. for a time of 10 seconds to 60 seconds, and at a pressure of 0.5 MPa to 15 MPa.

The first and second bonding subjects may be bonded to the sinter-bonding film using at least one of silver (Ag), gold (Au), copper (Cu), or nickel (Ni) as a surface metal layer of the first and second bonding subjects, and the second bonding subject may include a power semiconductor chip of a wide band gap compound.

The sinter-bonding film may reduce the oxide layer present on the surface of each particle in the metal powder through the reducing agent to remove the oxide layer from the surface during the thermal compression sinter-bonding process and may remove the residual resin through an ignition reaction of the film.

The sequentially placing the sinter-bonding film and the second bonding subject on the first bonding subject may further include placing a second tray containing a plurality of second bonding subjects around the heating stage, placing a third tray containing a large laminate material including an uncut preliminary sinter-bonding film and a preliminary carrier film around the heating stage, picking up the second bonding subject from the second tray using a fourth pick-up tool, placing the second bonding subject on the preliminary sinter-bonding film and the preliminary carrier film of the third tray using the fourth pick-up tool, and ripping the sinter-bonding film from the preliminary sinter-bonding film in the shape of the second bonding subject while contacting under pressure by stamping the second bonding subject on the preliminary sinter-bonding film to transfer the sinter-bonding film to the lower part of the second bonding subject, and placing the second bonding subject combined with the sinter-bonding film on the first bonding subject using the fourth pick-up tool and performing thermal compression sintering.

The applying the thermal compression sinter-bonding process to the first bonding subject, the sinter-bonding film and the second bonding subject may include bonding the first and second bonding subjects to the sinter-bonding film while performing the thermal compression sinter-bonding process on the first bonding subject, the sinter-bonding film, and the second bonding subject using the fourth pick-up tool and the heating stage, and the thermal compression sinter-bonding process may be performed in an air atmosphere or a nitrogen atmosphere at a temperature of 300° C. to 370° C. for a time of 10 seconds to 60 seconds, and at a pressure of 0.5 MPa to 15 MPa.

The first and second bonding subjects may be bonded to the sinter-bonding film using at least one of silver (Ag), gold (Au), copper (Cu), or nickel (Ni) as a surface metal layer of the first and second bonding subjects, and the second bonding subject may include a power semiconductor chip of a wide band gap compound.

The sinter-bonding film may reduce the oxide layer present on the surface of each particle in the metal powder through the reducing agent during the thermal compression sinter-bonding process to remove the oxide layer from the surface and may remove the residual resin through an ignition reaction of the film.

A method for manufacturing a sinter-bonding film according to the present invention,

In order to dispose the sinter-bonding film under a second bonding subject (or power semiconductor chip) based on a wide band gap compound semiconductor in a power semiconductor package,
a reducing agent and a resin are mixed with a copper powder that is subjected to acid treatment or non-treatment to allow the reducing agent to prevent oxidation on the surface of respective particles in the copper powder and to reduce an oxide layer remaining on each particle, while allowing the resin to link the respective particles to each other, and
it is thus possible to produce a sinter-bonding film that does not require complicated equipment to form a film shape, eliminates the bleeding problem during the sinter-bonding process, does not require an additional process such as post-washing after the sinter-bonding, and increases the sintering driving force of respective particles of copper powder within the film shape, and
it is thus possible to provide a sinter-bonding film that replaces a conventional sinter-bonding layer made of silver (Ag) particles under the second bonding subject, reduces manufacturing costs, effectively releases heat generated from a second bonding subject by directly contacting the bonding subject, and has long-term reliability at the operating temperature of the second bonding subject.

A method for manufacturing a power semiconductor package according to the present invention comprises:
to accommodate a second bonding subject (or power semiconductor chip) based on a wide band gap compound semiconductor in a power semiconductor package,
a first bonding subject, a sinter-bonding film, and a second bonding subject, which are sequentially laminated, are disposed in an air atmosphere or a nitrogen atmosphere, and the second bonding subject is thermally pressed to remove a reducing agent and an acrylic resin from the sinter-bonding film,
the copper oxide layer is reduced from the surface of respective particles of copper powder through the action of the reducing agent in the sinter-bonding film during the thermal pressing in an air atmosphere or a nitrogen atmosphere, thus ultimately causing sintering of the copper particles and allowing almost only copper metal to be left in the sinter-bonding film, and
high-speed sintering of respective particles of copper powder is possible to replace the conventional sinter-bonding layer made of silver (Ag) particles under the second bonding subject and the sinter-bonding film directly contacts the second bonding subject so that the sinter-bonding film ultimately maintains excellent mechanical properties even at the operating temperature of the second bonding subject, thereby significantly improving the long-term reliability of the second bonding subject.

### BRIEF DESCRIPTION OF THE DRAWINGS

FIG. 1 is a cross-sectional view schematically illustrating a conventional power semiconductor package.

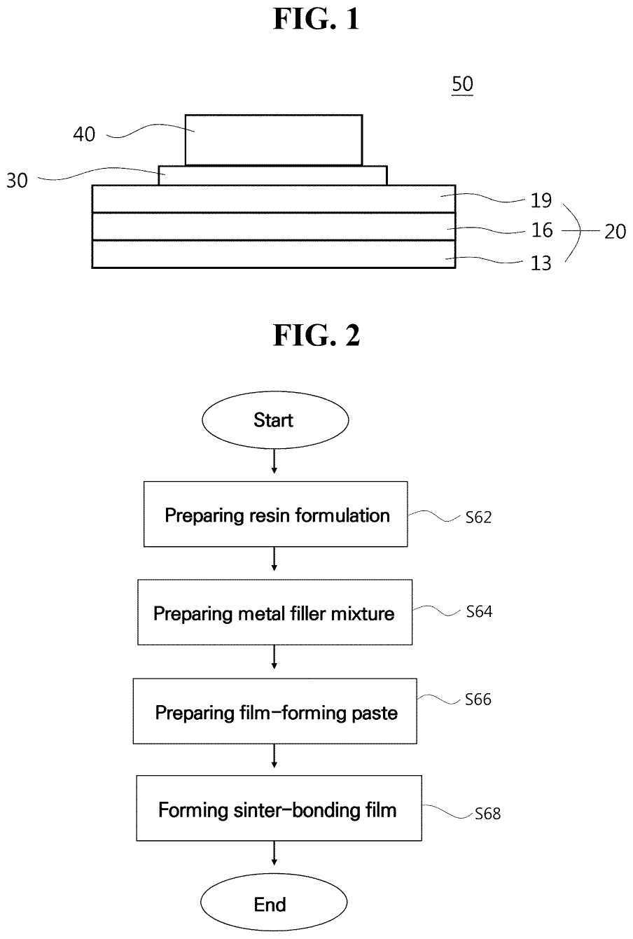

FIG. 2 is a flowchart illustrating a method for forming a sinter-bonding film according to the present invention.

FIG. 3 is a schematic diagram illustrating resin formulation in a first container.

FIG. 4 is a schematic diagram illustrating a metal powder in a second container.

FIG. 5 is a schematic diagram illustrating a metal filler mixture in the second container of FIG. 4.

FIGS. 6 and 7 are scanning electron microscope images showing the metal powder of FIG. 4 not subjected to acid treatment.

FIGS. 8 and 9 are scanning electron microscope images showing the metal powder of FIG. 4 subjected to acid treatment.

FIG. 10 is a schematic diagram illustrating a film-forming paste that is prepared by mixing the resin formulation of FIG. 3 with the metal filler mixture of FIG. 5 in the second container of FIG. 5.

FIG. 11 is a schematic diagram illustrating a preliminary sinter-bonding film formed by applying the film-forming paste of FIG. 10 to a preliminary carrier film using a doctor blade method.

FIG. 12 is a schematic diagram illustrating a preliminary sinter-bonding film formed by applying the film-forming paste of FIG. 10 to a preliminary carrier film using a screen printing method.

FIG. 13 is a schematic diagram illustrating a carrier film and a sinter-bonding film formed by repeatedly cutting the preliminary carrier film and the preliminary sinter-bonding film of FIGS. 11 and 12, respectively.

FIG. 14 is a scanning electron microscope image showing the sinter-bonding film of FIG. 13.

FIG. 15 is a flowchart illustrating a method for manufacturing a power semiconductor package according to the present invention.

FIG. 16 is a schematic diagram illustrating a method for manufacturing a power semiconductor package according to the flowchart of FIG. 15 in the first embodiment of the present invention.

FIG. 17 is a schematic diagram illustrating a method for manufacturing a power semiconductor package according to the flowchart of FIG. 15 in the second embodiment of the present invention.

FIG. 18 is a schematic diagram illustrating a sinter-bonding film formed using the preliminary carrier film and the preliminary sinter-bonding film of FIG. 13 in a different manner from FIG. 13 in the method for manufacturing the power semiconductor package of FIG. 17.

FIG. 19 is a perspective view schematically illustrating a power semiconductor package manufactured in FIG. 16 or FIG. 17 according to the flowchart of FIG. 15.

FIGS. 20 to 22 are graphs showing the results of the thermogravimetry-differential thermal analysis for the sinter-bonding film depending on the amount of resin in the sinter-bonding film of FIG. 13 or FIG. 18.

FIGS. 23 to 26 are graphs showing the shear strength after bonding in air of the power semiconductor chip depending on the bonding temperature and bonding time of the sinter-bonding film in the power semiconductor package of FIG. 19 when the metal powder in the sinter-bonding film is not subjected to acid treatment.

FIG. 27 is a comparative table showing the microstructure of the fracture surface of the power semiconductor chip and the sinter-bonding film after the shear strength test along with the various cross-sectional exposed parts of the sinter-bonding part formed in air in response to the change in the sinter-bonding time in the power semiconductor package of FIG. 19 when the metal powder in the sinter-bonding film is not subjected to acid treatment.

FIG. 28 is a comparative table showing the microstructure of the fracture surface of the power semiconductor chip and the sinter-bonding film after a shear strength test along with the various cross-sectional exposure parts of the sinter-bonding part formed in the air in response to the change in the amount of resin in the power semiconductor package of FIG. 19 when the metal powder in the sinter-bonding film is not subjected to acid treatment.

FIG. 29 is a graph showing the shear strength of the power semiconductor chip after bonding in the air depending on the bonding temperature and bonding time of the sinter-bonding film in the power semiconductor package of FIG. 19 when the metal powder in the sinter-bonding film is subjected to acid treatment.

FIG. 30 is a comparative table showing the microstructure of the fracture surface of the power semiconductor chip and the sinter-bonding film after a shear strength test along with the various cross-sectional exposed parts of the sinter-bonding part formed in the air after the amount of resin is fixed in the power semiconductor package of FIG. 19 when the metal powder in the sinter-bonding film is subjected to acid treatment.

FIGS. 31 and 32 are images showing the external shape of the sinter-bonding film depending on the amount of reducing agent in the sinter-bonding film after performing the thermal compression sinter-bonding process on the sinter-bonding film when the power semiconductor package of FIG. 19 is formed.

### DETAILED DESCRIPTION

Hereinafter, preferred embodiments of the present invention will be described in detail with reference to the attached drawings so that a person skilled in the art to which the present invention pertains can easily practice the present invention.

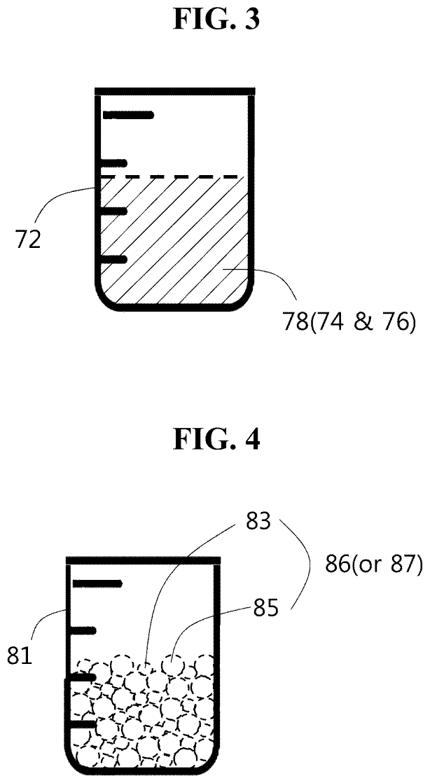

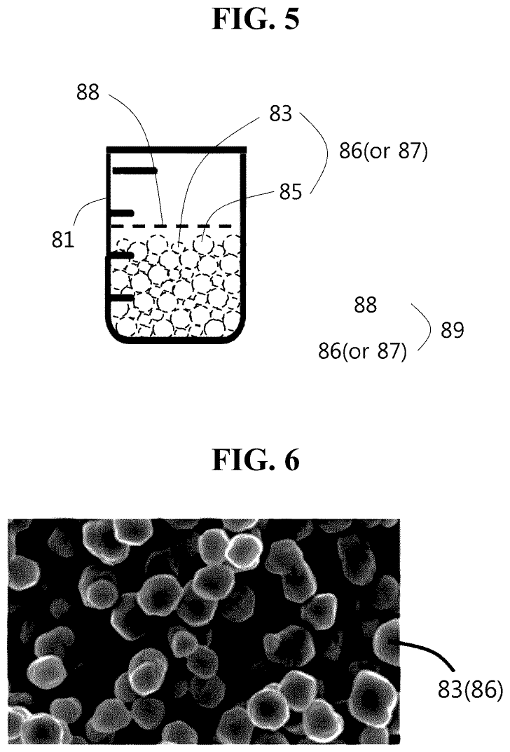

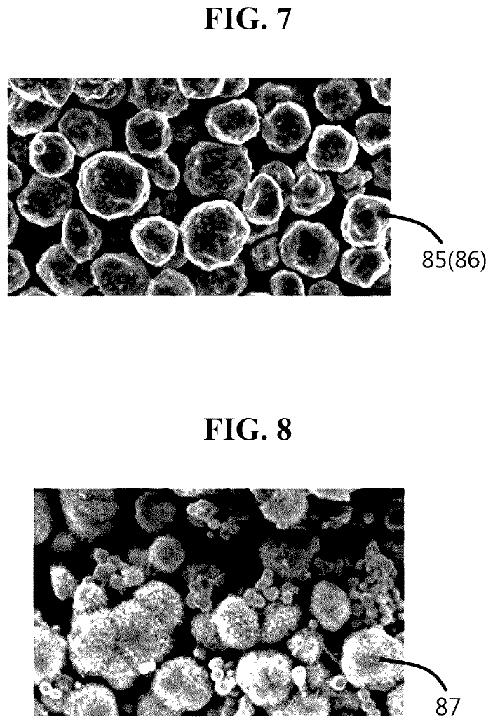

FIG. 2 is a flowchart illustrating a method for forming a sinter-bonding film according to the present invention, FIG. 3 is a schematic diagram illustrating a resin formulation in a first container, and FIG. 4 is a schematic diagram illustrating a metal powder in a second container.

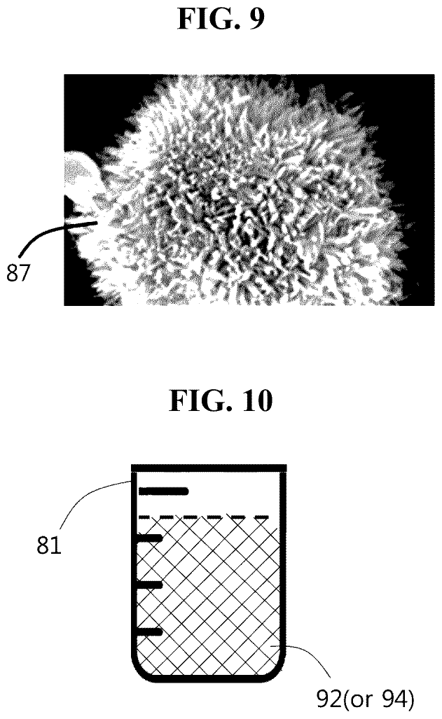

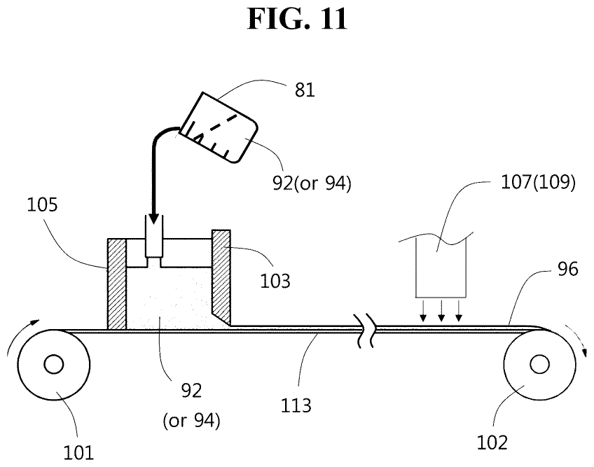

FIG. 5 is a schematic diagram illustrating a metal filler mixture in the second container of FIG. 4, and FIGS. 6 and 7 are scanning electron microscope images showing the metal powder of FIG. 4 not subjected to acid treatment.

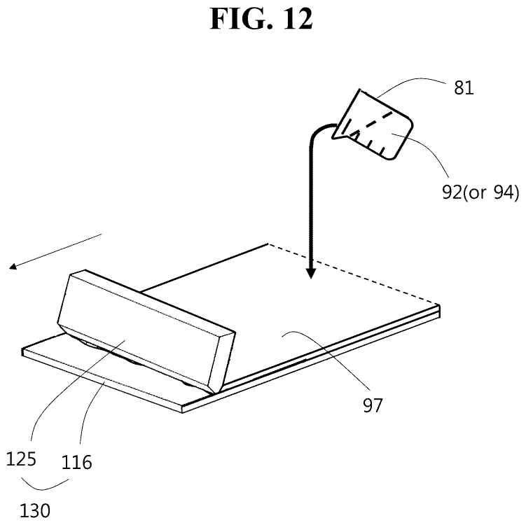

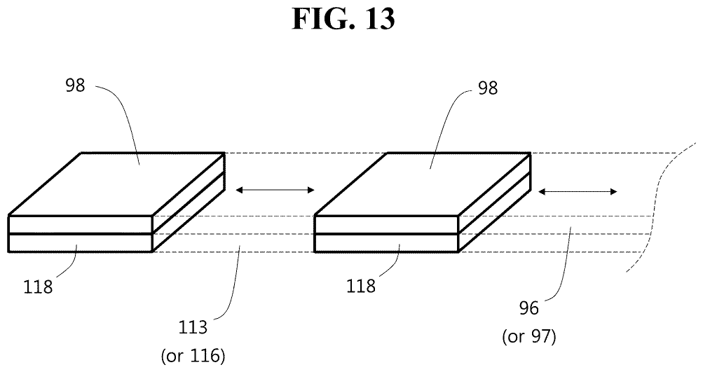

FIGS. 8 and 9 are scanning electron microscope images showing the metal powder of FIG. 4 subjected to acid treatment, and FIG. 10 is a schematic diagram illustrating a film-forming paste that is prepared by mixing the resin formulation of FIG. 3 with the metal filler mixture of FIG. 5 in the second container of FIG. 5.

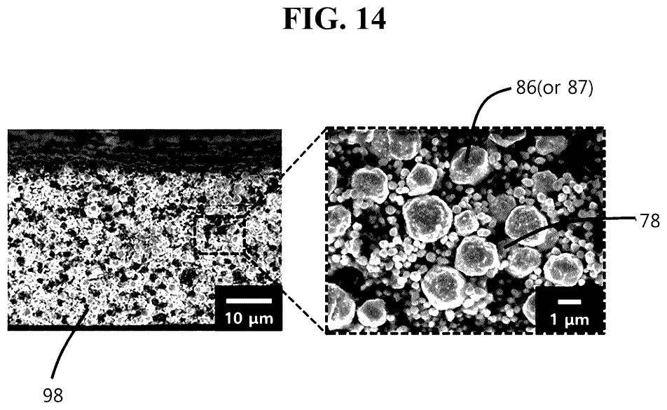

FIG. 11 is a schematic diagram illustrating a preliminary sinter-bonding film formed by applying the film-forming paste of FIG. 10 to a preliminary carrier film using a doctor blade method.

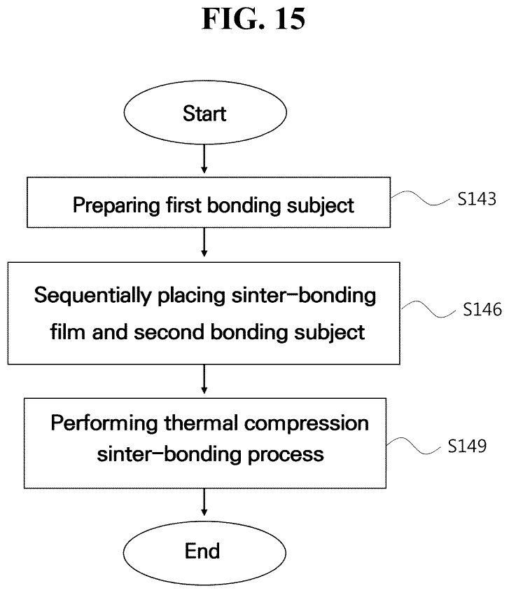

FIG. 12 is a schematic diagram illustrating a preliminary sinter-bonding film formed by applying the film-forming paste of FIG. 10 to a preliminary carrier film using a screen printing method.

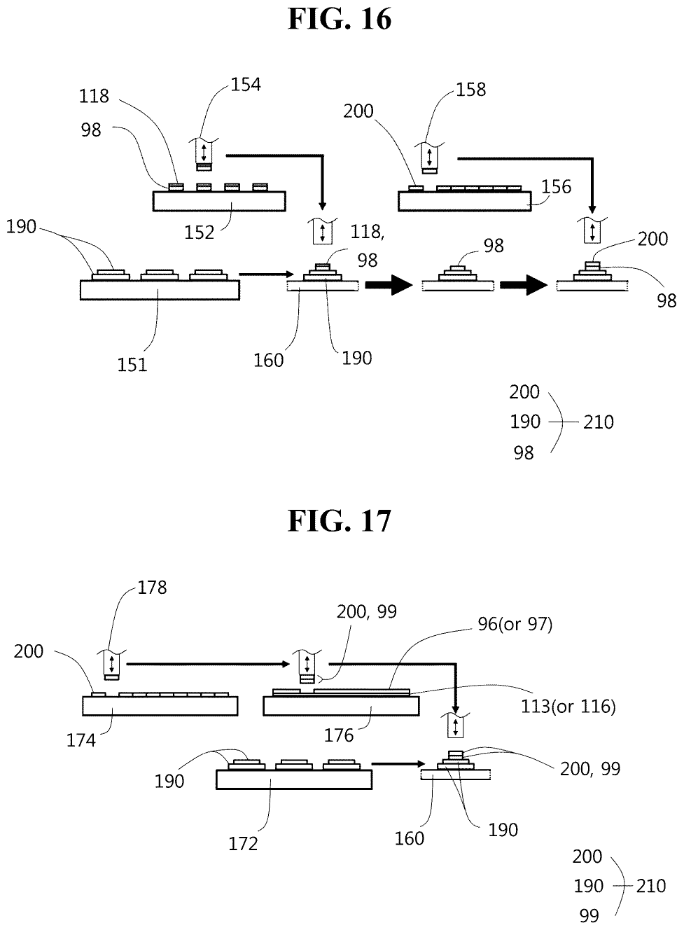

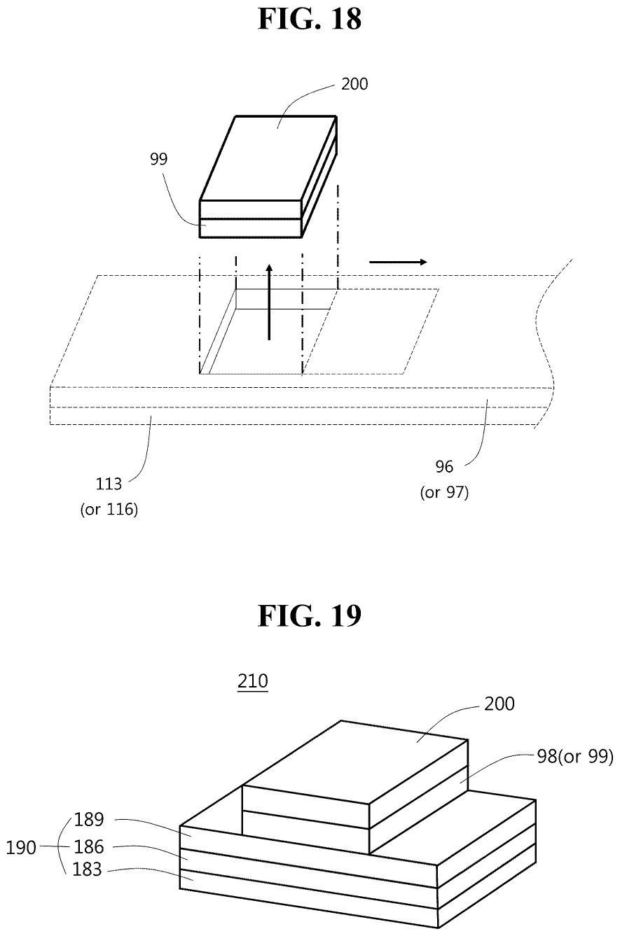

FIG. 13 is a schematic diagram illustrating a carrier film and a sinter-bonding film formed by repeatedly cutting the preliminary carrier film and the preliminary sinter-bonding film of FIGS. 11 and 12, respectively, and FIG. 14 is a scanning electron microscope image showing the sinter-bonding film of FIG. 13.

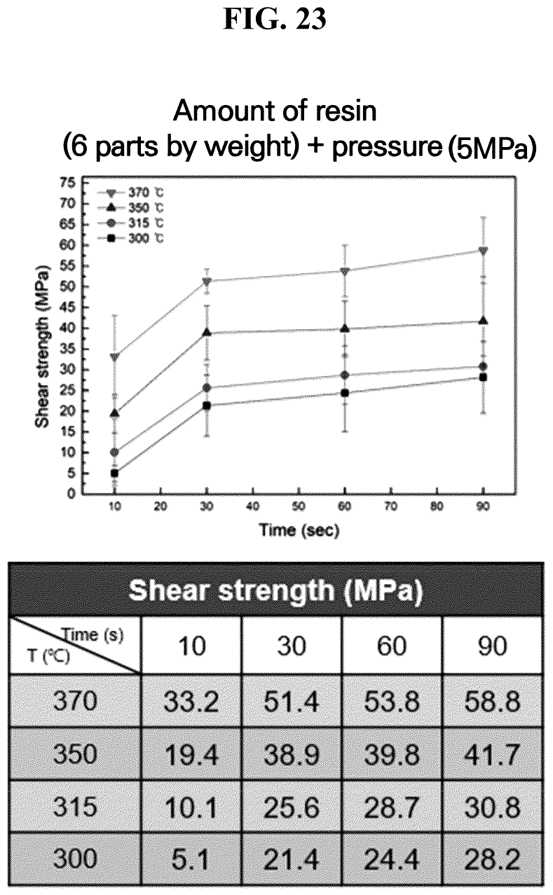

Referring to FIGS. 2 to 14, according to the flowchart of FIG. 2 (S62), a method for forming a sinter-bonding film (98 of FIG. 13 or 99 of FIG. 18) according to the present invention schematically includes preparing a resin formulation (78 of FIG. 3), preparing a metal filler mixture (89 of FIG. 5) (S64), mixing the resin formulation 78 with the metal filler mixture 89 to prepare a film-forming paste (92 or 94 of FIG. 10) (S66), and forming a sinter-bonding film 98 or 99 using the film-forming paste (92 or 94) (S68).

Here, referring to FIGS. 4 to 9, the metal filler mixture 89 contains a metal powder 86 or 87 and a reducing agent 88, and a copper (Cu) metal is applied to respective particles in the metal powder 86 or 87, and the surface of the respective particles in the metal powder 86 or 87 is subjected to acid treatment or non-treatment. More particularly, the preparing the resin formulation 78 (S62) includes filling a first container 72 with a resin 74, pouring a resin solvent 76 into the resin 74 in the first container 72, and dissolving the resin 74 using the resin solvent 76 to prepare a resin formulation.

The resin 74 and the resin solvent 76 are mixed in a weight ratio of 1:2 to 1:5 in the first container 72. When the weight ratio of the resin 74 to the resin solvent 76 does not fall within the range defined above, the resin 74 and the resin solvent 76 cannot form the sinter-bonding film 98 or 99 according to the present invention. The resin 74 is an acrylate polymer including at least one of polymethyl acrylate (PMA), polyethyl acrylate (PEA), poly(n-butyl acrylate) (PnBA), poly(2-ethylhexyl acrylate) (PEHA), or poly(2-hydroxyethyl acrylate) (PHEA), or a methacrylate polymer including at least one of polymethyl methacrylate (PMMA), poly(N-butyl methacrylate) (PnBMA), poly(iso-butyl methacrylate) (PIBMA), poly(2-hydroxyethyl methacrylate) (PEHMA), polyhydroxyethylmethacrylate (PHEMA), or poly(N,N-dimethylamino) ethyl methacrylate (PDMAEMA).

The resin solvent 76 is a ketone solvent including at least one of acetone or methyl ethyl ketone (MEK), a dipolar aprotic solvent including at least one of N-methyl pyrrolidone (NMP), dimethyl acetamide (DMAC), dimethyl formamide (DMF), or dimethyl sulfoxide (DMSO), an aromatic hydrocarbon including at least one of benzene or toluene, or chloroform, isopropanol, or tetrahydrofuran (THF).

Referring to FIGS. 4 to 7, the preparing a metal filler mixture 89 includes, when the metal powder 86 is not subjected to acid treatment, filling a second container 81 with the metal powder 86, and pouring a reducing agent 88 to the metal powder 86 into the second container 81. As shown in FIG. 4, the metal powder 86 includes first metal particles 83 having a first particle size, or includes first metal particles 83 having a first particle size and second metal particles 85 having a second particle size larger than the first particle size, and is formed by mixing the first metal particles 83 with the second metal particles 85 in a volume ratio of 100:0 to 26:74. The metal powder 86 may also include the second metal particles 85.

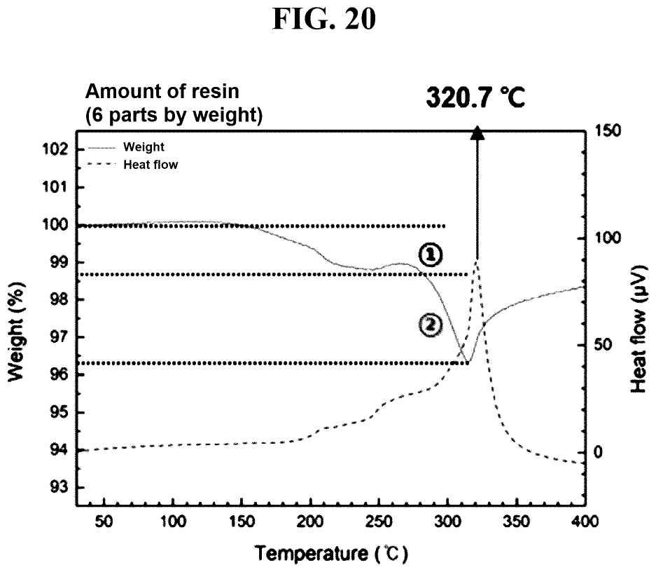

Each of the first metal particles 83 has a particle size of 100 nm to 900 nm. Each of the second metal particles 85 has a particle size of 1.5 μm to 25 μm. When the volume ratio and particle size of the first and second metal particles 83 and 85 do not fall within the ranges defined above, during the thermal compression sinter-bonding process in the manufacturing method of the power semiconductor package 210 of FIGS. 15 to 18, high-speed sinter-bonding of the sinter-bonding film 98 or 99 to first and second bonding subjects 190 and 200 is not effectively performed.

As shown in FIG. 5, the reducing agent 88 includes at least one of ethylene glycol, diethylene glycol, triethylene glycol (TEG), tetraethylene glycol (TTEG), polyethylene glycol (PEG), propylene glycol, dipropylene glycol, tripropylene glycol, polypropylene glycol, glycerol, 1,4-butanediol, 1,5-pentanediol, α-terpineol, diethyl toluene diamine, diethanol amine, or triethanol amine.

Referring to FIGS. 3, 5, 6, and 10, the preparing the film-forming paste 92 (S66) includes, when the metal powder 86 is not subjected to acid treatment, pouring the resin formulation 78 of the first container 72 into the metal filler mixture 89 of the second container 81 and mixing the metal filler mixture 89 with the resin formulation 78 in the second container 81. The film-forming paste 92 includes 6 to 10 parts by weight of the resin 74, 18 to 30 parts by weight of the resin solvent 76, and 0.5 to 2 parts by weight of the reducing agent 88 with respect to 100 parts by weight of the metal filler mixture 89. On the other hand, the preparing the film-forming paste 92 (S66) may be performed by pouring the metal filler mixture 89 of the second container 81 into the resin formulation 78 of the first container 72.

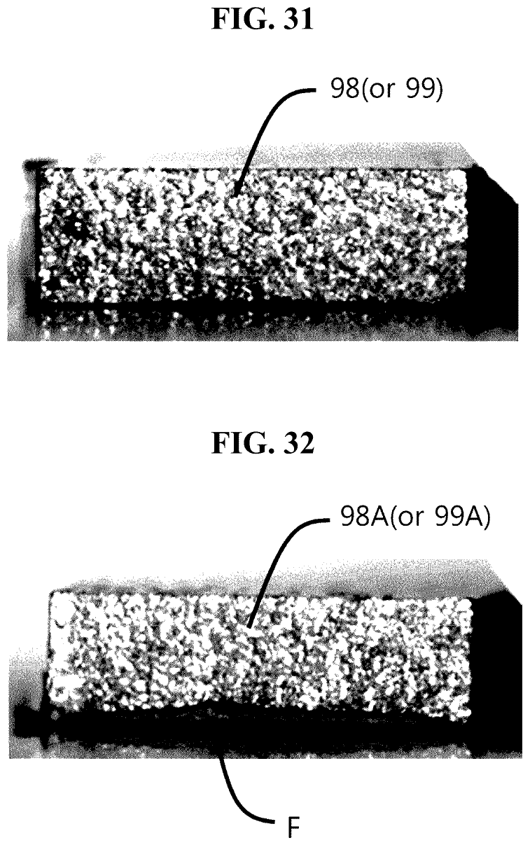

When the film-forming paste 92 contains the metal filler mixture 89, the resin 74, the resin solvent 76, and the reducing agent 88 in the parts by weight described above, after the sinter-bonding of the sinter-bonding film 98 or 99 to the first and second bonding subjects 190 and 200 during the thermal compression sinter-bonding process in the method for manufacturing the power semiconductor package 210 of FIGS. 15 to 18, the sinter-bonding film 98 or 99 can maintain the bonding part shape according to the present invention, as shown in FIG. 31.

However, when the amount of the resin 74 exceeds 6 to 10 parts by weight and the amount of the resin solvent 76 exceeds 18 to 30 parts by weight, the resin 74 and the resin solvent 76 do not form a sinter-bonding film 98 or 99 according to the present invention. When the amount of the reducing agent 88 is less than 0.5 parts by weight, cracks may occur during film formation and the sinter-bonding film 98 or 99 according to the present invention is not formed.

In addition, when the amount of the reducing agent 99 is greater than 2 parts by weight, upon sintering of the sinter-bonding film 98 or 99 to the first and second bonding subjects 190 and 200 during the thermal compression sinter-bonding process in the manufacturing method of the power semiconductor package 210 of FIGS. 15 to 18, the sinter-bonding film 98 or 99 may protrude from the interface of the first or second bonding subjects 190 or 200, thus forming an unwanted fillet F, and the sinter-bonding film 98 or 99 may be changed to an undesired sinter-bonding film 98A or 99A, as shown in FIG. 32, thus creating an uneven bonding part shape.

Referring to FIGS. 10 to 12, the forming a sinter-bonding film 98 or 99 (S68) includes, when the metal powder 86 is not subjected to acid treatment, pouring the film-forming paste 92 of the second container 81 into the preliminary carrier film 113 or 116 and thinly spreading the film-forming paste 92 onto the preliminary carrier film 113 using a blade 103 while moving the preliminary carrier film 113 using a doctor blade device 109, or thinly spreading the film-forming paste 92 onto the preliminary carrier film 116 using a squeegee 125 while fixing the preliminary carrier film 116 using a screen printing device 130. Here, during unwinding and winding of the preliminary carrier film 113 using two rollers 101 and 102, the doctor blade device 109 temporarily confines the film-forming paste 92 in the chamber 105 and flows the film-forming paste 92 from the chamber 105 to the preliminary carrier film 113 to control the coating thickness of the film-forming paste 92 using the blade 103 located on one side of the chamber 105.

In addition, referring to FIGS. 11 to 13, the forming the sinter-bonding film 98 or 99 (S68) further includes, when the metal powder 86 is not subjected to acid-treatment, drying the film-forming paste 92 on the preliminary carrier film 113 or 116 at a temperature of 75° C. to 120° C. for 1 to 5 minutes using a dryer (107 of FIG. 11; not shown in FIG. 12) to form a preliminary sinter-bonding film 96 or 97, and cutting the preliminary carrier film 113 or 116, and the preliminary sinter-bonding film 96 or 97 into a predetermined size, as shown in FIG. 13, or ripping a predetermined size of the preliminary sinter-bonding film 96 or 97 from the preliminary carrier film 113 or 116 (see FIG. 18).

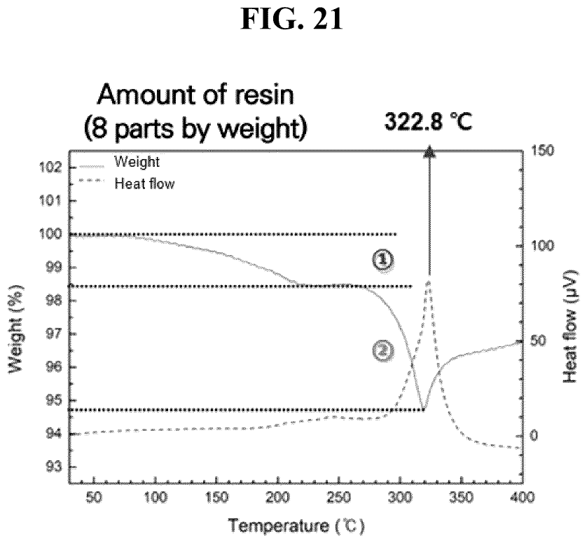

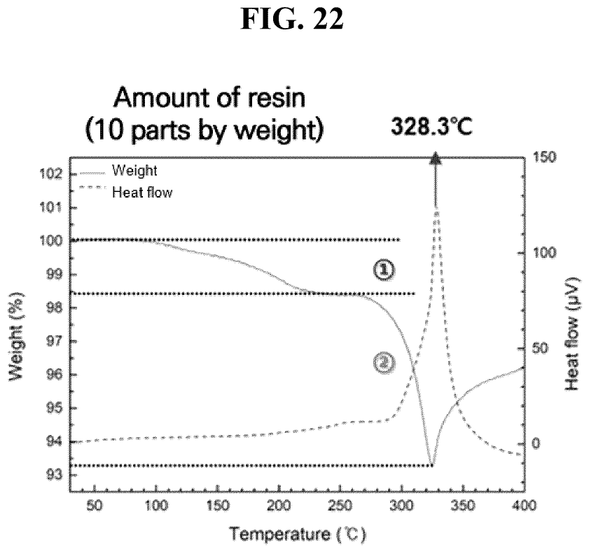

As a result, the sinter-bonding film 98 or 99 is formed using the preliminary sinter-bonding film 96 or 97, and the carrier film 118 is formed from the preliminary carrier film 113 or 116. In addition, the sinter-bonding film 98 or 99 is formed with the same size as the power semiconductor chip 200 as shown in FIG. 16, FIG. 17 or FIG. 18 from the preliminary sinter-bonding film 96 or 97 and the preliminary carrier film 113 or 116 along with the carrier film 118. Meanwhile, before performing the thermal compression sinter-bonding process for forming the power semiconductor package 210 as shown in FIG. 16, the carrier film 118 should be removed so that bonding at the upper and lower interfaces of the sinter-bonding film 98 or 99 can proceed smoothly.

Here, the reducing agent 88 and the resin formulation 78 remain along with the metal powder 86 in the preliminary sinter-bonding film 98 or 99 after drying the film-forming paste 92, as shown in FIG. 14. The reducing agent 88 surrounds the surface of respective particles in the metal powder 86 after drying the film-forming paste 92, thereby reducing the oxide layer on the surface of respective particles. The resin formulation 78 is disposed between the respective particles in the metal powder 86 after drying the film-forming paste 92, thereby connecting the respective particles as shown in FIG. 14. The resin solvent 76 is removed from the preliminary sinter-bonding film 96 or 97 during drying of the film-forming paste 92.

Meanwhile, unlike what has been described above, referring to FIGS. 4 and 5, the preparing the metal filler mixture 89 (S64) includes, when the metal powder 87 is subjected to acid treatment, filling the second container 81 with the metal powder 87, pouring a carboxyl group-containing acid (not shown in the drawing) into the metal powder 87 in the second container 81, acid-treating the surface of respective particles of the metal powder 87 using the carboxyl group-containing acid, and pouring a reducing agent 88 into the metal powder 87 in the second container 81.

Referring to FIGS. 4 and 5, the metal powder 87 may include first metal particles 83 having a first particle size or may include first metal particles 83 having the first particle size with second metal particles 85 having a second particle size larger than the first particle size, and may be prepared by mixing the first and second metal particles 83 and 85 in a volume ratio of 100:0 to 26:74. The carboxyl group-containing acid contains 1 to 5 parts by weight of carboxylic acid with respect to 100 parts by weight of alcohol in the second container 81. The metal powder 87 may also include the second metal particles 85.

Referring to FIGS. 4 and 5, each of the first metal particles 83 has a particle size of 100 nm to 900 nm. Each of the second metal particles 85 has a particle size of 1.5 μm to 25 μm. When the volume ratio and particle size of the first and second metal particles 83 and 85 do not fall within the ranges defined above, during the performance of the thermal compression sinter-bonding process in the manufacturing method of the power semiconductor package 210 of FIGS. 15 to 18, high-speed sinter-bonding of the sinter-bonding film 98 or 99 to the first and second bonding subjects 190 and 200 is not effectively performed.

The carboxylic acid includes at least one of formic acid, acetic acid, oxalic acid, malic acid, malonic acid, stearic acid, or succinic acid. Each particle of the metal powder 87 has a rough surface, as shown in FIGS. 8 and 9, after the surface of each particle in the metal powder 87 is treated with a carboxyl group-containing acid.

As shown in FIG. 5, the reducing agent 88 includes at least one of ethylene glycol, diethylene glycol, triethylene glycol (TEG), tetraethylene glycol (TTEG), polyethylene glycol (PEG), propylene glycol, dipropylene glycol, tripropylene glycol, polypropylene glycol, glycerol, 1,4-butanediol, 1,5-pentanediol, α-terpineol, diethyl toluene diamine, diethanol amine, or triethanol amine.

Referring to FIGS. 3, 5, 6, and 10, the preparing the film-forming paste 94 (S66) includes, when the metal powder 87 is subjected to acid treatment, pouring the resin formulation 78 of the first container 72 into the metal filler mixture 89 of the second container 81, and mixing the metal filler mixture 89 with the resin formulation 78 in the second container 81. Here, the film-forming paste 94 contains, 6 to 10 parts by weight of the resin 74, 18 to 30 parts by weight of the resin solvent 76, and 0.5 to 2 parts by weight of the reducing agent 88 with respect to 100 parts by weight of the metal filler mixture 89. On the other hand, the preparing the film-forming paste 94 (S66) may be performed by pouring the metal filler mixture 89 of the second container 81 into the resin formulation 78 of the first container 72 while treating the metal powder 87 with an acid.

When the metal filler mixture 89, the resin 74, the resin solvent 76, and the reducing agent 88 in the film-forming paste 94, are present in the parts by weight described above, after the sinter-bonding of the sinter-bonding film 98 or 99 to the first and second bonding subjects 190 and 200 during the thermal compression sinter-bonding process in the method for manufacturing the power semiconductor package 210 of FIG. 15 to 18, the sinter-bonding film 98 or 99 can maintain the shape according to the present invention, as shown in FIG. 31.

However, when the amount of the resin 74 does not fall within the range of 6 to 10 parts by weight and the amount of resin solvent 76 does not fall within the range of 18 to 30 parts by weight, the resin 74 and the resin solvent 76 do not form a sinter-bonding film 98 or 99 according to the present invention. When the amount of the reducing agent 88 is less than 0.5 parts by weight, cracks may occur during film formation and the sinter-bonding film 98 or 99 according to the present invention cannot be formed.

In addition, when the amount of the reducing agent 99 is greater than 2 parts by weight, upon sintering of the sinter-bonding film 98 or 99 to the first and second bonding subjects 190 and 200 during the thermal compression sinter-bonding process in the manufacturing method of the power semiconductor package 210 of FIGS. 15 to 18, the sinter-bonding film 98 or 99 may protrude from the interface of the first or second bonding subjects 190 or 200, thus forming an undesired fillet F, and the sinter-bonding film 98 or 99 may be changed to an undesired sinter-bonding film 98A or ( 99A, as shown in FIG. 32, thus creating an uneven bonding part shape.

Referring to FIGS. 10 and 12, the forming the sinter-bonding film 98 or 99 (S68) includes, when the metal powder 87 is subjected to acid treatment, pouring the film-forming paste 94 of the second container 81 onto the preliminary carrier film 113 or 116 and thinly spreading the film-forming paste 94 onto the preliminary carrier film 113 using a blade 103 while moving the preliminary carrier film 113 using a doctor blade device 109, or thinly spreading the film-forming paste 94 onto the preliminary carrier film 116 using the squeegee 125 while fixing the preliminary carrier film 116 using a screen printing device 130. Here, during unwinding and winding of the preliminary carrier film 113 using two rollers 101 and 102, the doctor blade device 109 temporarily confines the film-forming paste 94 in the chamber 105 and flows the film-forming paste 94 from the chamber 105 to the preliminary carrier film 113 to control the thickness of the film-forming paste 92 using the blade 103 located on one side of the chamber 105.

In addition, referring to FIGS. 10 to 13, the forming the sinter-bonding film 98 or 99 (S68) further includes, when the metal powder 87 is subjected to acid treatment, drying the film-forming paste 92 on the preliminary carrier film 113 or 116 at a temperature of 75° C. to 120°C. for 1 to 5 minutes using a dryer (107 of FIG. 11; not shown in FIG. 12) to form a preliminary sinter-bonding film 96 or 97, and cutting the preliminary carrier film 113 or 116 and the preliminary sinter-bonding film 96 or 97 into a predetermined size as shown in FIG. 13, or ripping a predetermined size of the preliminary sinter-bonding film 96 or 97 from the preliminary carrier film 113 or 116 (see FIG. 18).

As a result, the sinter-bonding film 98 or 99 is formed using the preliminary sinter-bonding film 96 or 97 and the carrier film 118 is formed from the preliminary carrier film 113 or 116. In addition, the sinter-bonding film 98 or 99 is formed with the same size as the power semiconductor chip 200 as shown in FIG. 16 or FIG. 17 or FIG. 18 from the preliminary sinter-bonding film 96 or 97 and the preliminary carrier film 113 or 116 along with the carrier film 118. Meanwhile, before performing the thermal compression sinter-bonding process for forming the power semiconductor package 210 as shown in FIG. 16 or FIG. 17, the carrier film 118 should be removed so that bonding at the upper and lower interfaces of the sinter-bonding film 98 or 99 can proceed smoothly.

Here, the reducing agent 88 and the resin formulation 78 remain along with the metal powder 86 in the preliminary sinter-bonding film 98 or 99 after drying the film-forming paste 94, as shown in FIG. 14. The reducing agent 88 surrounds the surface of respective particles in the metal powder 86 after drying the film-forming paste 94, thereby reducing the oxide layer on the surface of respective particles. The resin formulation 78 is disposed between the respective particles in the metal powder 86 after drying the film-forming paste 94, thereby connecting the respective particles as shown in FIG. 14. The resin solvent 76 is removed from the preliminary sinter-bonding film 96 or 97 during drying of the film-forming paste 94.

FIG. 15 is a flowchart illustrating a method for manufacturing a power semiconductor package according to the present invention, FIG. 16 is a schematic diagram illustrating a method for manufacturing a power semiconductor package according to the flowchart of FIG. 15 in the first embodiment of the present invention, and FIG. 17 is a schematic diagram illustrating a method for manufacturing a power semiconductor package according to the flowchart of FIG. 15 in the second embodiment of the present invention.

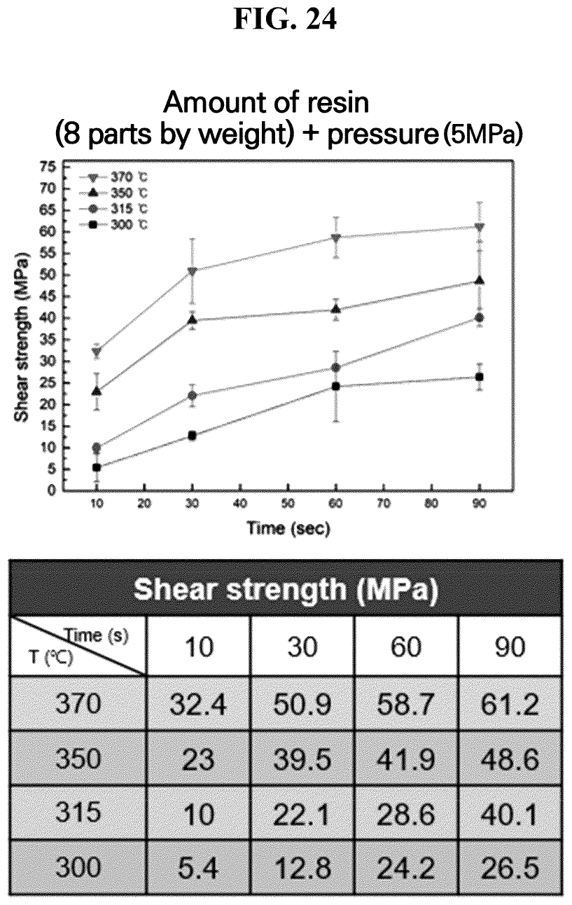

FIG. 18 is a schematic diagram illustrating a carrier film and a sinter-bonding film formed using the preliminary carrier film and the preliminary sinter-bonding film of FIG. 13 in a different manner from FIG. 13 in the method for manufacturing the power semiconductor package of FIG. 17 and FIG. 19 is a perspective view schematically illustrating a power semiconductor package manufactured in FIG. 16 or FIG. 17 according to the flowchart of FIG. 15.

In addition, FIGS. 31 and 32 are images showing the external shape of the sinter-bonding film depending on the amount of reducing agent in the sinter-bonding film after performing the thermal compression sinter-bonding process on the sinter-bonding film when the power semiconductor package of FIG. 19 is formed.

Referring to FIGS. 15 to 19 and FIGS. 31 and 32, a method for manufacturing a power semiconductor package (210 of FIG. 16 or FIG. 17 or FIG. 19) according to the present invention, schematically, according to the flowchart of FIG. 15, includes preparing a first bonding subject (190 of FIG. 16 or FIG. 17 or FIG. 18) on a heating stage (160 of FIG. 16 or FIG. 17) (S143), sequentially placing a sinter-bonding film (98 or 99 of FIG. 13 or FIG. 16 or FIG. 17 or FIG. 18) and a second bonding subject (200 of FIG. 16 or FIG. 17 or FIG. 18) on the first bonding subject 190 (S146), and applying a thermal compression sinter-bonding process to the first bonding subject 190, the sinter-bonding film 98 or 99, and the second bonding subject 200 (S149).

Here, the sinter-bonding film 98 or 99 is formed using a metal filler mixture (89 in FIG. 5) and a resin formulation (78 in FIG. 3) before application of the thermal compression sinter-bonding process. As shown in FIG. 5, the metal filler mixture 89 contains a metal powder 86 or 87 and a reducing agent (88 of FIG. 5), and a copper (Cu) metal is applied to respective particles in the metal powder 86 or 87, and the surface of the respective particles in the metal powder 86 or 87 is subjected to acid treatment or non-treatment.

Referring to FIGS. 4 and 5, the metal powder 86 may include first metal particles 83 having a first particle size or may include first metal particles 83 having a first particle size and second metal particles 85 having a second particle size larger than the first particle size, each of the first metal particles 83 has a particle size of 100 nm to 900 nm, each of the second metal particles 85 has a particle size of 1.5 μm to 25 μm, and the metal powder 86 is prepared by mixing the first and second metal particles 83 and 85 in a volume ratio of 100:0 to 26:74.

On the other hand, the metal powder 87 may include first metal particles 83 having a first particle size or may include first metal particles 83 having a first particle size and second metal particles 85 having a second particle size larger than the first particle size, each of the first metal particles 83 has a particle size of 100 nm to 900 nm, each of the second metal particles 85 has a particle size of 1.5 μm to 25 μm, the metal powder 87 is prepared by mixing the first and second metal particles 83 and 85 in a volume ratio of 100:0 to 26:74, and the surface of each first metal particle 83, or the surface of each first metal particle 83 and the surface of each second metal particle 85 may be acid-treated using a carboxyl group-containing acid.

The carboxyl group-containing acid contains 1 to 5 parts by weight of the carboxylic acid with respect to 100 parts by weight of the alcohol. The carboxylic acid includes at least one of formic acid, acetic acid, oxalic acid, malic acid, malonic acid, stearic acid, or succinic acid. As shown in FIGS. 8 and 9, when the surface of each particle in the metal powder 87 is acid-treated using the carboxyl group-containing acid, the surface of each particle in the metal powder 87 has a rough shape.

As shown in FIG. 3 or 14, the resin 74 is an acrylate polymer including at least one of polymethyl acrylate (PMA), polyethyl acrylate (PEA), poly(n-butyl acrylate) (PnBA), poly(2-ethylhexyl acrylate) (PEHA), or poly(2-hydroxyethyl acrylate) (PHEA), or a methacrylate polymer including at least one of polymethyl methacrylate (PMMA), poly(N-butyl methacrylate) (PnBMA), poly(iso-butyl methacrylate) (PIBMA), poly(2-hydroxyethyl methacrylate) (PEHMA), polyhydroxyethylmethacrylate (PHEMA), or poly(N,N-dimethylamino) ethyl methacrylate (PDMAEMA). The resin 74 is disposed between respective particles in the metal powder 86 or 87 to connect the particles.

As shown in FIG. 5, the reducing agent 88 includes at least one of ethylene glycol, diethylene glycol, triethylene glycol (TEG), tetraethylene glycol (TTEG), polyethylene glycol (PEG), propylene glycol, dipropylene glycol, tripropylene glycol, polypropylene glycol, glycerol, 1,4-butanediol, 1,5-pentanediol, α-terpineol, diethyl toluene diamine, diethanol amine, or triethanol amine.

The reducing agent 88 surrounds the surface of each particle in the metal powder 86 or 87 during the thermal compression sinter-bonding process to reduce the oxide layer on the surface thereof. The preparing the first bonding subject 190 on the heating stage 160 or 180 (S143) includes, as shown in FIG. 16 or FIG. 17, placing a first tray 151 or 172 having a plurality of first bonding subjects 190 around a heating stage 160 or 180, and placing the first bonding subject 190 from the first tray 151 or 172 on the heating stage 160 or 180 using a first pick-up tool (not shown in the drawing).

Here, the first pick-up tool may vacuum-absorb the first bonding subject 190. The first bonding subject 190 includes a direct bonded copper (DBC) substrate or an active brazing ceramic substrate, which includes a first copper layer 183, a metal oxide substrate layer 186, and a second copper layer 189 that are sequentially laminated as shown in FIG. 19. The sequentially placing the sinter-bonding film 98 and the second bonding subject 200 on the first bonding subject 190 (S146) includes, as shown in FIG. 16, placing a second tray 152 having a plurality of unit laminates, each including a sinter-bonding film 98 and a carrier film 118, around a heating stage 160, and placing a third tray 156 having a plurality of second bonding subjects 200 around the heating stage 160.

In addition, the sequentially placing the sinter-bonding film 98 and the second bonding subject 200 on the first bonding subject 190 (S146) further includes, as shown in FIG. 16, placing the sinter-bonding film 98 and the carrier film 118 on the first bonding subject 190 from the second tray 152 using the second pick-up tool 154, separating the carrier film 118 from the sinter-bonding film 98, and placing the second bonding subject 200 on the sinter-bonding film 98 from the third tray 156 using the third pick-up tool 158.

The second pick-up tool 154 may vacuum-absorb the sinter-bonding film 98 and the carrier film 118. The third pick-up tool 158 may vacuum-absorb the second bonding subject 200. The applying a thermal compression sinter-bonding process to the first bonding subject 190, the sinter-bonding film 98, and the second bonding subject 200 (S149) includes bonding the first and second bonding subjects 190 and 200 to the sinter-bonding film 98 while performing the thermal compression sinter-bonding process on the first bonding subject 190, the sinter-bonding film 98, and the second bonding subject 200 using the heating stage 160 and the third pick-up tool 158. Here, the third pick-up tool 158 may have the same heating function as the heating stage 160.

The third pick-up tool 158 may replace the first pickup tool (not shown in the drawing) and the second pickup tool 154. The thermal compression sinter-bonding process is performed under an air atmosphere or a nitrogen atmosphere at a temperature of 300° C. to 370°C. for 10 to 60 seconds and at a pressure of 0.5 to 15 MPa. The second bonding subject 200 may have a surface metal layer (not shown in the drawing) on a surface that contacts the upper portion of the sinter-bonding film 98. In addition, the first bonding subject 190 may have a second copper layer 189 as a surface metal layer on a surface that contacts the lower portion of the sinter-bonding film 98. Here, the first and second bonding subjects 190 and 200 are bonded to the sinter-bonding film 98 using at least one of silver (Ag), gold (Au), copper (Cu), or nickel (Ni) as the surface bonding layer of the first and second bonding subjects 190 and 200, as shown in FIG. 19. The second bonding subject 200 includes, but is not limited to, a power semiconductor chip of a wide band gap compound as shown in FIG. 19, and may be, for example, a semiconductor chip or other element that generates a great amount of heat on the sinter-bonding film 98.

When the temperature, time, and pressure of thermal compression sinter-bonding process do not fall within the ranges defined above, the high-speed sinter-bonding of the sinter-bonding film 98 to the first and second bonding subjects 190 and 200 is not effectively performed during the thermal compression sinter-bonding process in the method of manufacturing the power semiconductor package 210 of FIGS. 15 to 18. For example, when the pressure is less than 0.5 MPa in the thermal compression sinter-bonding process, the pressure is not sufficiently transmitted to the metal powder 86 or 87 in the sinter-bonding film 98 and thus the rearrangement of each particle in the metal powder 86 or 87 may be reduced and the high-speed sinter-bonding characteristics of the sinter-bonding film 98 to the first and second bonding subjects 190 and 200 may be deteriorated. In addition, when the pressure is greater than 15 MPa in the thermal compression sinter-bonding process, at least one of the first or second bonding subjects 190 or 200 may be destroyed by the pressure.

As shown in FIG. 16, during the thermal compression sinter-bonding process, the sinter-bonding film 98 removes the oxide layer from the surface by reducing the oxide layer on the surface of each particle in the metal powder 86 or 87 by a reducing agent 88, and removes the residual resin 74 through the ignition reaction of the film. The first bonding subject 190, the sinter-bonding film 98, and the second bonding subject 200 constitute a power semiconductor package 210 as shown in FIG. 19.

On the other hand, the sequentially placing the sinter-bonding film 99 and the second bonding subject 200 on the first bonding subject 190 (S146) is performed by, as shown in FIG. 17, placing a second tray 174 having a plurality of second bonding subjects 200 around the heating stage 180, placing a third tray 176 having a large laminate material including an uncut preliminary sinter-bonding film (96 or 97 of FIG. 18) and a preliminary carrier film (113 or 116 of FIG. 18) around the heating stage 180, picking up the second bonding subject 200 from the second tray 174 using a fourth pick-up tool 178, and placing the preliminary sinter-bonding film 96 or 97 of the third tray 176 and the second bonding subject 200 on the preliminary carrier film 113 or 116, and ripping the sinter-bonding film 99 from the preliminary sinter-bonding film 96 or 97 in the shape of the second bonding subject 200 while contacting under pressure by stamping the second bonding subject 200 on the preliminary sinter-bonding film 96 or 97, as shown in FIG. 18, to transfer the sinter-bonding film to the lower part of the second bonding subject.

Here, as shown in FIGS. 17 and 18, the sinter-bonding film 99 is ripped from the preliminary sinter-bonding film 96 or 97 under the second bonding subject 200 in the same shape as the second bonding subject 200 by the stamping and vacuum suction of the fourth pick-up tool 178, and is transferred to the lower part of the second bonding subject 200. On the other hand, the preliminary carrier film 113 or 116 supports the preliminary sinter-bonding film 96 or 97 on the third tray 176, but is not ripped by the stamping and vacuum suction of the fourth pick-up tool 178. In addition, the sequentially placing the sinter-bonding film 99 and the second bonding subject 200 on the first bonding subject 190 (S146) may further include placing the second bonding subject 200 combined with the sinter-bonding film 99 on the first bonding subject 190 using the fourth pick-up tool 178 and performing thermal compression sinter-bonding, as shown in FIG. 17.

The applying a thermal compression sinter-bonding process to the first bonding subject 190, the sinter-bonding film 99, and the second bonding subject 200 (S149) may include bonding the first and second bonding subjects 190 and 200 to the sinter-bonding film 99 while performing the thermal compression sinter-bonding process on the first bonding subject 190, the sinter-bonding film 99, and the second bonding subject 200 using the fourth pick-up tool 178 and the heating stage 180. Here, the fourth pick-up tool 178 may have the same heating function as the heating stage 180. The thermal compression sinter-bonding process is performed under an air atmosphere or a nitrogen atmosphere at a temperature of 300° C. to 370°C. for 10 to 60 seconds and at a pressure of 0.5 to 15 MPa.

The second bonding subject 200 may have a surface metal layer (not shown in the drawing) on a surface that contacts the upper portion of the sinter-bonding film 99. In addition, the first bonding subject 190 may have a second copper layer 189 as a surface metal layer on a surface that contacts the lower portion of the sinter-bonding film 99. Here, the first and second bonding subjects 190 and 200 are bonded to the sinter-bonding film 98 using at least one of silver (Ag), gold (Au), copper (Cu), or nickel (Ni) as the surface bonding layer of the first and second bonding subjects 190 and 200, as shown in FIG. 19. The second bonding subject 200 includes, but is not limited to, a power semiconductor chip of a wide band gap compound, as shown in FIG. 19, and may be, for example, a semiconductor chip or other element that generates a great amount of heat on the sinter-bonding film 99.

When the temperature, time, and pressure of the thermal compression sinter-bonding process do not fall within the ranges defined above, the high-speed sinter-bonding of the sinter-bonding film 99 to the first and second bonding subjects 190 and 200 is not effectively performed during the thermal compression sinter-bonding process in the manufacturing method of the power semiconductor package 210 of FIGS. 15 to 18. For example, when the pressure is less than 0.5 MPa in the thermal compression sinter-bonding process, the pressure is not sufficiently transmitted to the metal powder 86 or 87 in the sinter-bonding film 98 and thus the rearrangement of each particle in the metal powder 86 or 87 may be reduced and the high-speed sinter-bonding characteristics of the sinter-bonding film 99 to the first and second bonding subjects 190 and 200 may be deteriorated. In addition, when the pressure is greater than 15 MPa in the thermal compression sinter-bonding process, at least one of the first or second bonding subject 190 or 200 may be destroyed by the pressure.

As shown in FIG. 17, during the thermal compression sinter-bonding process, the sinter-bonding film 99 reduces the oxide layer on the surface of each particle in the metal powder 86 or 87 by a reducing agent 88 to remove the oxide layer from the surface, and removes the residual resin 74 through the ignition reaction of the film. The first bonding subject 190, the sinter-bonding film 98, and the second bonding subject 200 constitute a power semiconductor package 210 as shown in FIG. 19.

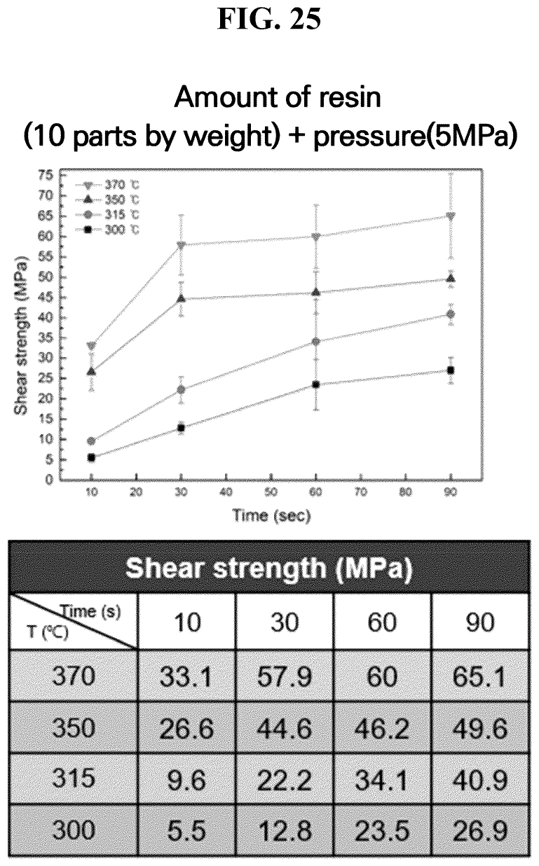

FIGS. 20 to 22 are graphs showing the results of the measurement of the weight-heat simultaneous measurement device for the sinter-bonding film depending on the amount of resin in the sinter-bonding film of FIG. 13 or FIG. 18.

Referring to FIGS. 20 to 22, when the first metal particles 83 in the sinter-bonding film (98 of FIG. 13 or 99 of FIG. 18) have a particle size of 350 nm as an average diameter, the second metal particles 85 have a particle size of 2 μm as an average diameter, and the first and second metal particles 83 and 85 are not subjected to acid treatment, the sinter-bonding film gradually forms an exothermic peak that is proportional to the amount of resin 74 (6 to 10 parts by weight) during the thermal compression sinter-bonding process.

The exothermic peak is generated when the surface oxide layer of each of the first and second metal particles 83 and 85 is removed by the ignition reaction of the film and the reduction action of the reducing agent around the thermal decomposition temperature of the resin 74 of 320° C., and then sintering between the first and second metal particles 83 and 85 rapidly progresses. Therefore, the exothermic peak affects the actual temperature of the thermal compression sinter-bonding process when the sinter-bonding film 98 or 99 is sintered to the first and second bonding subjects 190 and 200. The amount of exothermic heat changes depending on the amount of resin 74 and thus is ultimately affected by the degree of sintering between the first and second metal particles 83 and 85.

Here, the section \textcircled{1} is the thermal decomposition area of the reducing agent, and the section \textcircled{2} is the thermal decomposition section of the resin. Meanwhile, the sinter-bonding film 98 or 99 may be replaced with a sinter-bonding film (98 or 99; the metal powder is subjected to acid treatment). This is because the sinter-bonding film (98 or 99; the metal powder is subjected to acid treatment) more effectively removes metal oxide layers on the surface of each of the first and second metal particles 83 and 85 than the sinter-bonding film 98 or 99. Hereinafter, in order to simplify the description of the present invention, the sinter-bonding film 98 or 99 may be referred to as a “sinter-bonding film containing a metal powder not subjected to acid treatment” or as a “sinter-bonding film containing a metal powder subjected to acid treatment”.

In addition, if necessary, in order to clarify the description of the present invention, the sinter-bonding film (98 or 99; the metal powder is not subjected to acid treatment) may be referred to as a “sinter-bonding film containing a metal powder not subjected to acid treatment”, or the sinter-bonding film (98 or 99; the metal powder is subjected to acid treatment) may be referred to as a “sinter-bonding film containing a metal powder subjected to acid treatment”.

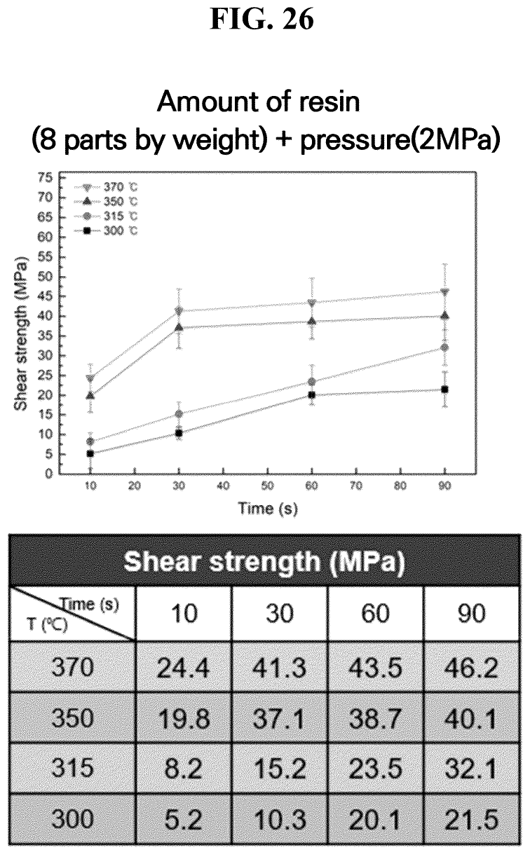

FIGS. 23 to 26 are graphs showing the shear strength after bonding in air of the power semiconductor chip depending on the bonding temperature and bonding time of the sinter-bonding film in the power semiconductor package of FIG. 19 when the metal powder in the sinter-bonding film is not subjected to acid treatment.

Referring to FIGS. 23 to 26, when, in the sinter-bonding film (98 of FIG. 13 or 99 of FIG. 18), the first metal particles 83 have a particle size of 350 nm as an average diameter, the second metal particles 85 have a particle size of 2 μm as an average diameter, and the first and second metal particles 83 and 85 are not subjected to acid treatment, the sinter-bonding film 98 or 99 has different shear strengths due to differences in exothermic peaks (see the graphs of FIGS. 20 to 22) depending on the amount of resin 74 (6 to 10 parts by weight) during the thermal compression sinter-bonding process.

That is, when a pressure of 5 MPa is applied to the sinter-bonding film 98 or 99 in the thermal compression sinter-bonding process, the sinter-bonding film 98 or 99 had a shear strength of 15 MPa or more in all formed bonding parts after bonding for a predetermined time when sintering was performed on 6, 8, and 10 weight parts of the resin at 300° C. to 370° C., as shown in FIGS. 23 to 25. In addition, when a pressure of 2 MPa was applied to the sinter-bonding film 98 or 99 that was formed by subjecting 8 parts by weight of resin to the thermal compression sinter-bonding process, the sinter-bonding film 98 or 99 had a shear strength of 15 MPa or more in all formed bonding parts after bonding for a predetermined time when sintering was performed at 300°C. to 370° C., as shown in FIG. 26. According to the DA(Die Attach)-5 consortium, the shear strength of the die-attach bonding part in the power semiconductor package 210 requires a minimum value of 15 MPa.

In conclusion, the thermal compression sinter-bonding process is preferably performed for 60 seconds or longer at a temperature (300°C. or 315° C.) lower than the resin decomposition temperature (approximately 320° C.), and for about 10 seconds at a temperature (350 or 370°C.) higher than the resin decomposition temperature. Meanwhile, the sinter-bonding film 98 or 99 may be replaced with a sinter-bonding film (98 or 99; metal powder is subjected to acid treatment). This is because the sinter-bonding film (98 or 99; metal powder is subjected to acid treatment) more effectively removes the metal oxide layer on the surface of each of the first and second metal particles 83 and 85 than the sinter-bonding film 98 or 99.

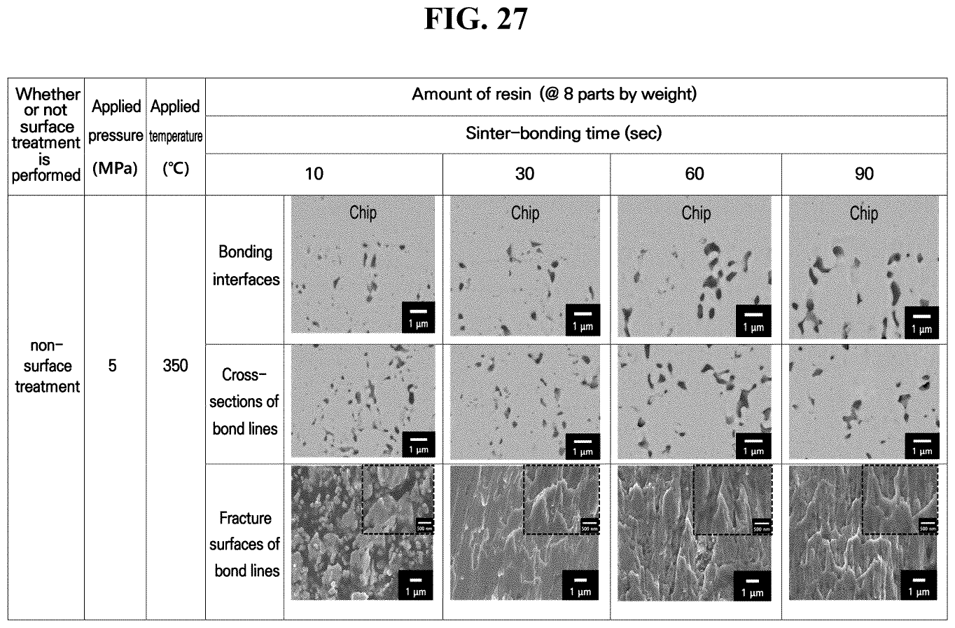

FIG. 27 is a comparative table showing the microstructure of the fracture surface of the power semiconductor chip and the sinter-bonding film after the shear strength test along with the various cross-sectional exposed parts of the sinter-bonding part formed in air in response to the change in the sinter-bonding time in the power semiconductor package of FIG. 19 when the metal powder in the sinter-bonding film is not subjected to acid treatment.

Referring to FIG. 27, when, in the sinter-bonding film (98 of FIG. 13 or 99 of FIG. 18), the first metal particles 83 have a particle size of 350 nm as an average diameter, the second metal particles 85 have a particle size of 2 μm as an average diameter, and a sinter-bonding film 98 or 99 of 8 parts by weight of resin is bonded between first and second bonding subjects 190 and 200 under the conditions of 5 MPa and 350° C. for different sinter-bonding times, without acid treatment of the first and second metal particles 83 and 85, all of the cross-section of the bonding interface between the chip (second bonding subject 200) and the sinter-bonding film 98 or 99, the cross-section of the sinter-bonding film 98 or 99 having the bonding part, and the internal fracture surface of the bonding film formed by fracturing the bonded sinter-bonding film 98 or 99 using a shear test had a dense microstructure.

Meanwhile, the sinter-bonding film 98 or 99 may be replaced with a sinter-bonding film (99; metal powder is subjected to acid treatment). This is because the sinter-bonding film (99; metal powder is subjected to acid treatment) more effectively removes the metal oxide layer on the surface of each of the first and second metal particles 83 and 85 than the sinter-bonding film 98 or 99.

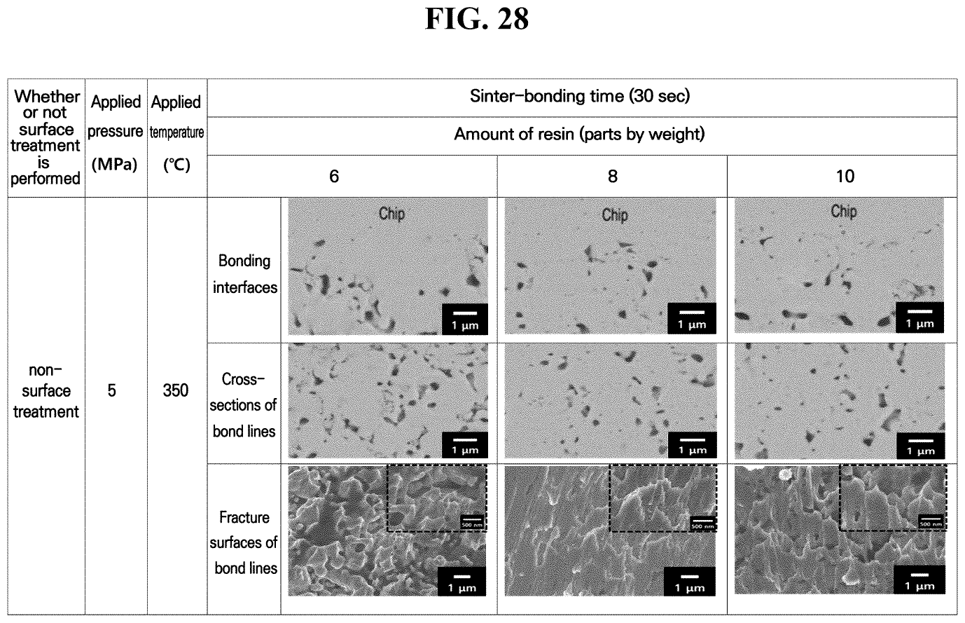

FIG. 28 is a comparative table showing the microstructure of the fracture surface of the power semiconductor chip and the sinter-bonding film after a shear strength test along with the various cross-sectional exposure parts of the sinter-bonding part formed in the air in response to the change in the amount of resin in the power semiconductor package of FIG. 19 when the metal powder in the sinter-bonding film is not subjected to acid treatment.

Referring to FIG. 28, when, in the sinter-bonding film (98 of FIG. 13 or 99 of FIG. 18), the first metal particles 83 have a particle size of 350 nm as an average diameter, the second metal particles 85 have a particle size of 2 μm as an average diameter, and the sinter-bonding film 98 or 99 is bonded between first and second bonding subjects 190 and 200 using an amount of a resin (6 to 10 parts by weight) under the conditions of 5 MPa and 350° C. for 30 seconds, without acid treatment of the first and second metal particles 83 and 85, all of the cross-section of the bonding interface between the chip (second bonding subject 200) and the sinter-bonding film 98 or 99, the cross-section of the sinter-bonding film 98 or 99 having the bonding part, and the internal fracture surface of the bonding film formed by fracturing the bonded sinter-bonding film 98 or 99 using a shear test had a dense microstructure.

Meanwhile, the sinter-bonding film 98 or 99 may be replaced with a sinter-bonding film (99; metal powder is subjected to acid treatment). This is because the sinter-bonding film (99; metal powder is subjected to acid treatment) more effectively removes the metal oxide layer on the surface of each of the first and second metal particles 83 and 85 than the sinter-bonding film 98.

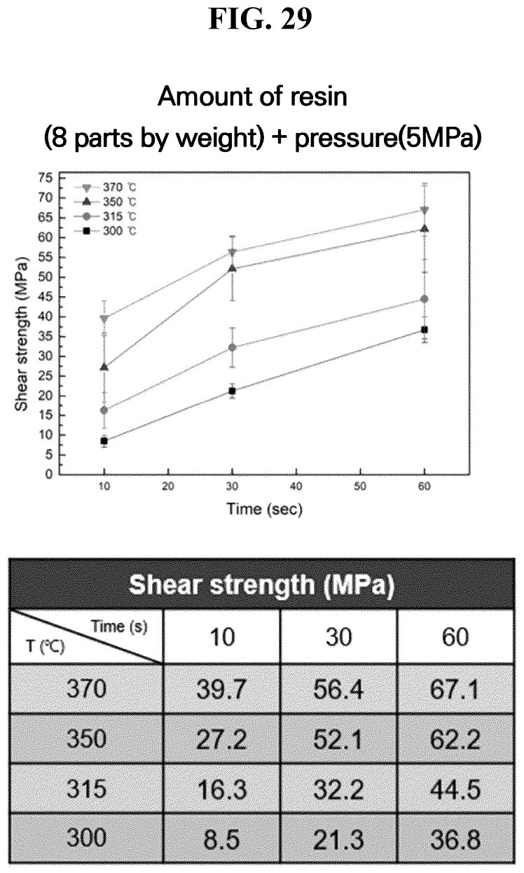

FIG. 29 is a graph showing the shear strength of the power semiconductor chip after bonding in the air depending on the bonding temperature and bonding time of the sinter-bonding film in the power semiconductor package of FIG. 19 when the metal powder in the sinter-bonding film is subjected to acid treatment.

Referring to FIG. 29, when, in the sinter-bonding film (98 of FIG. 13 or 99 of FIG. 18), the first metal particles 83 have a particle size of 350 nm as an average diameter, the second metal particles 85 have a particle size of 2 μm as an average diameter, and the sinter-bonding film 98 or 99 is bonded using 8 parts by weight of a resin between first and second bonding subjects 190 and 200 under the conditions of 5 MPa and 315° C. to 370° C., upon acid treatment of the first and second metal particles 83 and 85, all had a shear strength of 15 MPa or greater at a bonding time of 10 seconds or longer. In addition, the sinter-bonding film 98 or 99 had a shear strength of 15 MPa or greater when the bonding time was 30 seconds or longer at 300° C.

The sinter-bonding film 98 or 99 had greater shear strength under the same bonding conditions than the sinter-bonding film (98 or 99; metal powder was subjected to acid treatment). In conclusion, it is preferable that the sinter-bonding process be performed for 10 seconds or 30 seconds or longer at a temperature (300° C., 315° C.) lower than the resin decomposition temperature (approximately 320° C.), and for about 10 seconds at a temperature (350° C., 370° C.) higher than the resin decomposition temperature.

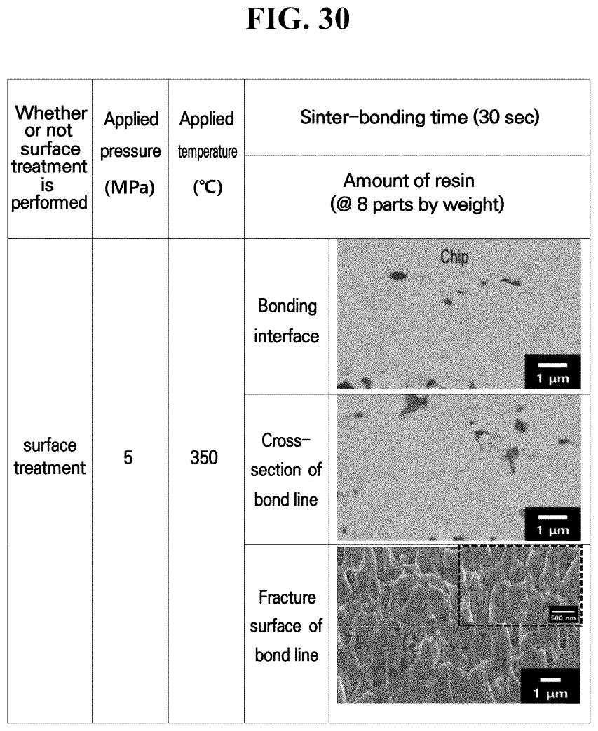

FIG. 30 is a comparative table showing the microstructure of the fracture surface of the power semiconductor chip and the sinter-bonding film after a shear strength test along with the various cross-sectional exposed parts of the sinter-bonding part formed in the air after the amount of resin is fixed in the power semiconductor package of FIG. 19 when the metal powder in the sinter-bonding film is subjected to acid treatment.

Referring to FIG. 30, when, in the sinter-bonding film (98 of FIG. 13 or 99 of FIG. 18), the first metal particles 83 have a particle size of 350 nm as an average diameter, the second metal particles 85 have a particle size of 2 μm as an average diameter, and a sinter-bonding film 98 or 99 is bonded using 8 parts by weight of a resin between first and second bonding subjects 190 and 200 under the conditions of 5 MPa and 350° C. for 30 seconds, upon acid treatment of the first and second metal particles 83 and 85, all of the cross-section of the bonding interface between the chip (second bonding subject 200) and the sinter-bonding film 98 or 99, the cross-section of the sinter-bonding film 98 or 99 having the bonding part, and the internal fracture surface of the bonding film formed by fracturing the bonded sinter-bonding film 98 or 99 using a shear test had a dense microstructure. That is, the sinter-bonding film 98 or 99 had a denser microstructure than the sinter-bonding film (98 or 99; the metal powder is not subjected to acid treatment) when compared to the results of FIGS. 27 and 28.

1. A method of forming a sinter-bonding film comprising:
preparing a resin formulation;
preparing a metal filler mixture;
mixing the resin formulation with the metal filler mixture to prepare a film-forming paste; and
forming a sinter-bonding film using the film-forming paste,
wherein the metal filler mixture comprises:
a metal powder; and
a reducing agent,
wherein a copper (Cu) metal corresponds to respective particles of the metal powder and
a surface of each particle in the metal powder is subjected to acid treatment or non-treatment.

2. The method according to claim 1, wherein the preparing a resin formulation comprises:
filling a first container with a resin;
pouring a resin solvent into the resin in the first container; and
dissolving the resin using the resin solvent to prepare a resin formulation,
wherein the resin and the resin solvent are mixed in a weight ratio of 1:2 to 1:5 in the first container.

3. The method according to claim 2, wherein the resin is an acrylate polymer including at least one of polymethyl acrylate (PMA), polyethyl acrylate (PEA), poly(n-butyl acrylate) (PnBA), poly(2-ethylhexyl acrylate) (PEHA), or poly(2-hydroxyethyl acrylate) (PHEA), or a methacrylate polymer including at least one of polymethyl methacrylate (PMMA), poly(N-butyl methacrylate) (PnBMA), poly(iso-butyl methacrylate) (PIBMA), poly(2-hydroxyethyl methacrylate) (PEHMA), polyhydroxyethylmethacrylate (PHEMA), or poly(N,N-dimethylamino) ethyl methacrylate (PDMAEMA).

4. The method according to claim 2, wherein the resin solvent is a ketone solvent including at least one of acetone or methyl ethyl ketone (MEK), a dipolar aprotic solvent including at least one of N-methyl pyrrolidone (NMP), dimethyl acetamide (DMAC), dimethyl formamide (DMF), or dimethyl sulfoxide (DMSO), an aromatic hydrocarbon including at least one of benzene or toluene, or chloroform, isopropanol, or tetrahydrofuran (THF).

5. The method according to claim 2, wherein the preparing a metal filler mixture comprises:
filling the second container with the metal powder; and
pouring the reducing agent into the metal powder in the second container,
wherein the metal powder comprises first metal particles having a first particle size, or comprises first metal particles having a first particle size and second metal particles having a second particle size larger than the first particle size, and
the metal powder is prepared by mixing the first metal particles with the second metal particles in a volume ratio of 100:0 to 26:74.

6. The method according to claim 5, wherein each of the first metal particles has a particle size of 100 nm to 900 nm and
each of the second metal particles has a particle size of 1.5 μm to 25 μm.

7. The method according to claim 5, wherein the reducing agent includes at least one of ethylene glycol, diethylene glycol, triethylene glycol (TEG), tetraethylene glycol (TTEG), polyethylene glycol (PEG), propylene glycol, dipropylene glycol, tripropylene glycol, polypropylene glycol, glycerol, 1,4-butanediol, 1,5-pentanediol, α-terpineol, diethyl toluene diamine, diethanol amine, or triethanol amine.

8. The method according to claim 5, wherein the preparing a film-forming paste comprises:
pouring the resin formulation of the first container into the metal filler mixture of the second container; and
mixing the metal filler mixture with the resin formulation in the second container,
wherein the film-forming paste comprises:
6 to 10 parts by weight of the resin;
18 to 30 parts by weight of the resin solvent; and
0.5 to 2 parts by weight of the reducing agent,
with respect to 100 parts by weight of the metal filler mixture.

9. The method according to claim 8, wherein the forming a sinter-bonding film comprises:
pouring the film-forming paste of the second container onto a preliminary carrier film;
spreading the film-forming paste thinly on the preliminary carrier film through a blade while moving the preliminary carrier film using a doctor blade device, or spreading the film-forming paste thinly on the preliminary carrier film through a squeegee while fixing the preliminary carrier film using a screen printing device;
drying the film-forming paste on the preliminary carrier film at a temperature of 75° C. to 120° C. for 1 minute to 5 minutes to form a preliminary sinter-bonding film; and
cutting the preliminary carrier film and the preliminary sinter-bonding film into a predetermined size, or ripping the preliminary sinter-bonding film on the preliminary carrier film into a predetermined size.

10. The method according to claim 9, wherein the reducing agent and the resin are left along with the metal powder in the preliminary sinter-bonding film after drying the film-forming paste,
the reducing agent surrounds the surface of each particle in the metal powder and reduces the oxide layer on the surface of each particle after drying the film-forming paste,
the resin is disposed between respective particles in the metal powder after drying the film-forming paste to connect the particles, and
the resin solvent is removed from the preliminary sinter-bonding film while drying of the film-forming paste.

11. The method according to claim 2, wherein the preparing a metal filler mixture comprises:
filling a second container with a metal powder;
pouring a carboxyl group-containing acid into the metal powder in the second container to acid-treat the surface of each particle of the metal powder using the carboxyl group-containing acid; and
pouring the reducing agent into the metal powder in the second container,
wherein the metal powder comprises first metal particles having a first particle size, or comprises first metal particles having a first particle size and second metal particles having a second particle size larger than the first particle size,
the metal powder is prepared by mixing the first metal particles with the second metal particles in a volume ratio of 100:0 to 26:74, and
the carboxyl group-containing acid comprises 1 to 5 parts by weight of the carboxylic acid with respect to 100 parts by weight of the alcohol in the second container.

12. The method according to claim 11, wherein each first metal particle has a particle size of 100 nm to 900 nm and
each second metal particle has a particle size of 1.5 μm to 25 μm.

13. The method according to claim 11, wherein the carboxylic acid comprises at least one of formic acid, acetic acid, oxalic acid, malic acid, malonic acid, stearic acid, or succinic acid.

14. The method according to claim 11, wherein each particle in the metal powder has a rough shape after acid-treating the surface of each particle in the metal powder using the carboxyl group-containing acid.

15. The method according to claim 11, wherein the reducing agent comprises at least one of ethylene glycol, diethylene glycol, triethylene glycol (TEG), tetraethylene glycol (TTEG), polyethylene glycol (PEG), propylene glycol, dipropylene glycol, tripropylene glycol, polypropylene glycol, glycerol, 1,4-butanediol, 1,5-pentanediol, α-terpineol, diethyl toluene diamine, diethanol amine, or triethanol amine.

16. The method according to claim 11, wherein the preparing a film-forming paste comprises:
pouring the resin formulation of the first container into the metal filler mixture of the second container; and
mixing the metal filler mixture with the resin formulation in the second container,
wherein the film-forming paste comprises:
6 to 10 parts by weight of the resin;
18 to 30 parts by weight of the resin solvent; and
0.5 to 2 parts by weight of the reducing agent,
with respect to 100 parts by weight of the metal filler mixture.

17. The method according to claim 16, wherein the forming a sinter-bonding film comprises:
pouring the film-forming paste of the second container onto a preliminary carrier film; and
spreading the film-forming paste thinly on the preliminary carrier film through a blade while moving the preliminary carrier film using a doctor blade device, or spreading the film-forming paste thinly on the preliminary carrier film through a squeegee while fixing the preliminary carrier film using a screen printing device;
drying the film-forming paste on the preliminary carrier film at a temperature of 75° C. to 120° C. for 1 minute to 5 minutes to form a preliminary sinter-bonding film; and
cutting the preliminary carrier film and the preliminary sinter-bonding film into a predetermined size, or ripping the preliminary sinter-bonding film on the preliminary carrier film into a predetermined size.

18. The method according to claim 17, wherein the reducing agent and the resin are left along with the metal powder in the preliminary sinter-bonding film after drying the film-forming paste,
the reducing agent surrounds the surface of each particle in the metal powder along with the carboxyl group-containing acid and reduces the oxide layer on the surface of each particle after drying the film-forming paste,
the resin is disposed between respective particles in the metal powder after drying the film-forming paste to connect the particles, and
the resin solvent is removed from the preliminary sinter-bonding film after drying of the film-forming paste.

19. A method of manufacturing a power semiconductor package comprising:
preparing a first bonding subject on a heating stage;
sequentially placing a sinter-bonding film and a second bonding subject on the first bonding subject; and
applying a thermal compression sinter-bonding process to the first bonding subject, the sinter-bonding film and the second bonding subject,
wherein the sinter-bonding film is formed using a metal filler mixture and a resin formulation before the thermal compression sinter-bonding process,
the metal filler mixture comprises a metal powder and a reducing agent,
a copper (Cu) metal is applied to each particle in the metal powder, and
a surface of each particle in the metal powder is subjected to acid treatment or non-treatment.

20. The method according to claim 19, wherein the metal powder comprises first metal particles having a first particle size, or comprises first metal particles having a first particle size and second metal particles having a second particle size larger than the first particle size,
each of the first metal particles has a particle size of 100 nm to 900 nm and each of the second metal particles has a particle size of 1.5 μm to 25 μm, and
the metal powder is prepared by mixing the first metal particles with the second metal particles in a volume ratio of 100:0 to 26:74.

21. The method according to claim 19, wherein the metal powder comprises first metal particles having a first particle size, or comprises first metal particles having a first particle size and second metal particles having a second particle size larger than the first particle size,
each of the first metal particles has a particle size of 100 nm to 900 nm and each of the second metal particles has a particle size of 1.5 μm to 25 μm,
the metal powder is prepared by mixing the first metal particles with the second metal particles in a volume ratio of 100:0 to 26:74, and
the surface of each first metal particle is acid-treated using the carboxyl group-containing acid or the surface of each first metal particle and each second metal particle is acid-treated using the carboxyl group-containing acid.

22. The method according to claim 21, wherein the carboxyl group-containing acid comprises 1 to 5 parts by weight of carboxylic acid with respect to 100 parts by weight of alcohol, and
the carboxylic acid comprises at least one of formic acid, acetic acid, oxalic acid, malic acid, malonic acid, stearic acid, or succinic acid.

23. The method according to claim 21, wherein each particle in the metal powder has a rough shape after acid-treatment of the surface of each particle in the metal powder using the carboxyl group-containing acid.

24. The method according to claim 19, wherein the resin is an acrylate polymer including at least one of polymethyl acrylate (PMA), polyethyl acrylate (PEA), poly(n-butyl acrylate) (PnBA), poly(2-ethylhexyl acrylate) (PEHA), or poly(2-hydroxyethyl acrylate) (PHEA), or is a methacrylate polymer including at least one of polymethyl methacrylate (PMMA), poly(N-butyl methacrylate) (PnBMA), poly(iso-butyl methacrylate) (PIBMA), poly(2-hydroxyethyl methacrylate) (PEHMA), polyhydroxyethylmethacrylate (PHEMA), or poly(N,N-dimethylamino) ethyl methacrylate (PDMAEMA), and
the resin is disposed between the respective particles in the metal powder to connect the particles.

25. The method according to claim 19, wherein the reducing agent comprises at least one of ethylene glycol, diethylene glycol, triethylene glycol (TEG), tetraethylene glycol (TTEG), polyethylene glycol (PEG), propylene glycol, dipropylene glycol, tripropylene glycol, polypropylene glycol, glycerol, 1,4-butanediol, 1,5-pentanediol, α-terpineol, diethyl toluene diamine, diethanol amine, or triethanol amine, and
the reducing agent surrounds the surface of each particle in the metal powder and reduces the oxide layer on the surface of each particle during the thermal compression sinter-bonding process.

26. The method according to claim 19, wherein the preparing the first bonding subject on the heating stage comprises:
placing a first tray containing a plurality of first bonding subjects around the heating stage; and
placing the first bonding subject from the first tray on the heating stage using a first pick-up tool,
wherein the first bonding subject comprises a direct bonded copper (DBC) substrate or an active brazing ceramic substrate, which comprises a first copper layer, a metal oxide substrate layer, and a second copper layer that are sequentially laminated.

27. The method according to claim 19, wherein the sequentially placing the sinter-bonding film and the second bonding subject on the first bonding subject comprises:
placing a second tray containing a plurality of unit laminates, each including the sinter-bonding film and the carrier film, around the heating stage;
placing a third tray containing a plurality of second bonding subjects around the heating stage;
placing the sinter-bonding film and the carrier film on the first bonding subject from the second tray using a second pick-up tool;
separating the carrier film from the sinter-bonding film; and
placing the second bonding subject on the sinter-bonding film from the third tray using a third pick-up tool.

28. The method according to claim 27, wherein the applying the thermal compression sinter-bonding process to the first bonding subject, the sinter-bonding film and the second bonding subject comprises bonding the first and second bonding subjects to the sinter-bonding film while performing the thermal compression sinter-bonding process on the first bonding subject, the sinter-bonding film, and the second bonding subject using the heating stage and the third pick-up tool, and
the thermal compression sinter-bonding process is performed in an air atmosphere or a nitrogen atmosphere at a temperature of 300° C. to 370°C. for a time of 10 seconds to 60 seconds, and at a pressure of 0.5 MPa to 15 MPa.

29. The method according to claim 28, wherein the first and second bonding subjects are bonded to the sinter-bonding film using at least one of silver (Ag), gold (Au), copper (Cu), or nickel (Ni) as a surface metal layer of the first and second bonding subjects, and
the second bonding subject comprises a power semiconductor chip of a wide band gap compound.

30. The method according to claim 28, wherein the sinter-bonding film reduces the oxide layer present on the surface of each particle in the metal powder through the reducing agent to remove the oxide layer from the surface during the thermal compression sinter-bonding process and removes the residual resin through an ignition reaction of the film.

31. The method according to claim 19, wherein the sequentially placing the sinter-bonding film and the second bonding subject on the first bonding subject further comprises:
placing a second tray containing a plurality of second bonding subjects around the heating stage;
placing a third tray containing a large laminate material including an uncut preliminary sinter-bonding film and a preliminary carrier film around the heating stage;
picking up the second bonding subject from the second tray using a fourth pick-up tool;
placing the second bonding subject on the preliminary sinter-bonding film and the preliminary carrier film the third tray using the fourth pick-up tool, and ripping the sinter-bonding film from the preliminary sinter-bonding film in the shape of the second bonding subject while contacting under pressure by stamping the second bonding subject on the preliminary sinter-bonding film to transfer the sinter-bonding film to the lower part of the second bonding subject; and
placing the second bonding subject combined with the sinter-bonding film on the first bonding subject using the fourth pick-up tool and performing thermal compression sintering.

32. The method according to claim 31, wherein the applying the thermal compression sinter-bonding process to the first bonding subject, the sinter-bonding film and the second bonding subject comprises bonding the first and second bonding subjects to the sinter-bonding film while performing the thermal compression sinter-bonding process on the first bonding subject, the sinter-bonding film, and the second bonding subject using the fourth pick-up tool and the heating stage, and
the thermal compression sinter-bonding process is performed in an air atmosphere or a nitrogen atmosphere at a temperature of 300° C. to 370°C. for a time of 10 seconds to 60 seconds, and at a pressure of 0.5 MPa to 15 MPa.

33. The method according to claim 32, wherein the first and second bonding subjects are bonded to the sinter-bonding film using at least one of silver (Ag), gold (Au), copper (Cu), or nickel (Ni) as a surface metal layer of the first and second bonding subjects, and
the second bonding subject comprises a power semiconductor chip of a wide band gap compound.

34. The method according to claim 32, wherein the sinter-bonding film reduces the oxide layer present on the surface of each particle in the metal powder through the reducing agent during the thermal compression sinter-bonding process to remove the oxide layer from the surface and remove the residual resin through an ignition reaction of the film.
